(19) United States
(12) Patent Application Publication
(10) Pub. No.: US 2026/0282487 A1
(43) Pub. Date: Sep. 17, 2026

(54) CONTACT STRUCTURE, SEMICONDUCTOR DEVICE WITH THE SAME, AND METHOD FOR FABRICATING THE SAME

(71) Applicant: NANYA TECHNOLOGY CORPORATION, NEW TAIPEI CITY (TW)

(72) Inventor: PING HSU, NEW TAIPEI CITY (TW)

(21) Appl. No.: 19/081,162

(22) Filed: Mar. 17, 2025

(51) Int. Cl. H10D 64/23; H01L 21/768; H01L 23/528; H10D 62/832; H10D 62/834; H10D 64/62

(52) U.S. Cl. CPC H10D 64/257; H10D 62/832; H10D 62/8325; H10D 62/834; H10D 64/62; H10W 20/43; H10W 20/435; H10W 20/072; H10W 20/46

(57) ABSTRACT

The present application discloses a cell contact structure, a semiconductor device, and a method for fabricating the semiconductor device. The cell contact structure includes a bottom contact layer positioned on a substrate and enclosed by a plurality of bit line structures and a plurality of partition layers; a liner layer positioned between the bottom contact layer and the substrate, between the bottom contact layer and the plurality of bit line structures, and between the bottom contact layer and the plurality of partition layers; and a top contact layer positioned on the bottom contact layer and the liner layer. A top surface of the bottom contact layer and a top surface of the liner layer are substantially coplanar. The liner layer includes doped polycrystalline silicon, doped polycrystalline germanium, or doped polycrystalline silicon germanium. The bottom contact layer includes tungsten, titanium, or titanium nitride.

### TECHNICAL FIELD

The present disclosure relates to a cell contact structure, a semiconductor device, and a method for fabricating the semiconductor device, and more particularly, to a semiconductor device having a cell contact structure with a liner layer, and a method for fabricating the semiconductor device.

### DISCUSSION OF THE BACKGROUND

Semiconductor devices are used in various electronic applications, including personal computers, cellular telephones, digital cameras, and other electronic equipment. Sizes of semiconductor devices are continuously decreasing to meet growing demands for computing power. However, such scaling down presents challenges that are becoming more frequent and impactful. Therefore, there are still challenges to improving quality, yield, performance and reliability while reducing complexity.

This Discussion of the Background section is provided for background information only. The statements in this Discussion of the Background are not an admission that the subject matter disclosed in this Discussion of the Background section constitutes prior art to the present disclosure, and no part of this Discussion of the Background section may be used as an admission that any part of this application, including this Discussion of the Background section, constitutes prior art to the present disclosure.

### SUMMARY

One aspect of the present disclosure provides a semiconductor device comprising a substrate having a plurality of impurity regions; two bit line structures formed on the substrate, extending along a first direction, and separated from each other; two partition layers positioned on the substrate, extending along a second direction perpendicular to the first direction, separated from each other along the first direction, and simultaneously contacting the two bit line structures; and a cell contact structure disposed over the substrate. The cell contact structure comprises a bottom contact layer positioned on the substrate and enclosed by the two bit line structures and the two partition layers. The cell contact structure also comprises a liner layer positioned between the substrate and the bottom contact layer, between the two bit line structures and the bottom contact layer, and between the two partition layer and the bottom contact layer. The cell contact structure further comprises a top contact layer positioned on the liner layer and the bottom contact layer. The two bit line structures comprise an air gap disposed therebetween.

Another aspect of the present disclosure provides a semiconductor device comprising a substrate; a plurality of impurity regions disposed in the substrate; two bit line structures formed on the substrate, extending along a first direction, and separated from each other; two partition layers positioned on the substrate, extending along a second direction perpendicular to the first direction, separated from each other along the first direction, and simultaneously contacting the two bit line structures; a cell contact structure disposed over the substrate; a conductive pillar positioned on the cell contact structure; a landing pad disposed on the conductive pillar; and a stack of dielectric layers disposed on the substrate and comprising at least one dielectric layers. The two bit line structures comprise a first air gap disposed therebetween. The cell contact structure comprises a bottom contact layer positioned on the substrate and enclosed by the two bit line structures and the two partition layers. The cell contact structure also comprises a liner layer positioned between the substrate and the bottom contact layer, between the two bit line structures and the bottom contact layer, and between the two partition layer and the bottom contact layer. The cell contact structure further comprises a top contact layer positioned on the liner layer and the bottom contact layer. The plurality of impurity regions are formed of silicon phosphide, phosphorus-doped silicon carbon, silicon carbide, silicon germanium, silicon-germanium-tin alloy, or silicon-germanium-boron alloy. A sidewall of the conductive pillar is laterally recessed from a sidewall of the landing pad. A dielectric layer of the stack of dielectric layers is configured as a thicker dielectric layer laterally surrounding the conductive pillars and the landing pad. A plurality of second air gaps are sealed in the thicker dielectric layer and alternating with the conductive pillars.

Another aspect of the present disclosure provides a method for fabricating a semiconductor device including providing a substrate; forming two bit line structures on the substrate, extending along a first direction, and separated from each other; forming a plurality of spacer structures on sides of the two bit line structures; forming an air gap between the two bit line structures; forming two partition layers on the substrate, extending along a second direction perpendicular to the first direction, separated from each other, and resulting in a contact opening in conjunction with the plurality of spacer structures; conformally forming a liner layer in the contact opening and within the contact opening; forming a bottom contact layer on the liner layer and within the contact opening; and forming a top contact layer on the liner layer, on the bottom contact layer, and within the contact opening. The liner layer, the bottom contact layer, and the top contact layer together configure a cell contact structure.

Another aspect of the present disclosure provides a method for fabricating a semiconductor device including providing a substrate with a plurality of active area; forming a plurality of impurity regions in the substrate; forming two bit line structures on the substrate, extending along a first direction, and separated from each other; forming a plurality of spacer structures on sides of the two bit line structures; forming a first air gap between the two bit line structures; forming two partition layers on the substrate, extending along a second direction perpendicular to the first direction, separated from each other, and resulting in a contact opening in conjunction with the plurality of spacer structures; conformally forming a liner layer in the contact opening and within the contact opening; forming a bottom contact layer on the liner layer and within the contact opening; and forming a top contact layer on the liner layer, on the bottom contact layer, and within the contact opening. The plurality of impurity regions are formed of silicon phosphide, phosphorus-doped silicon carbon, silicon carbide, silicon germanium, silicon-germanium-tin alloy, or silicon-germanium-boron alloy. The liner layer, the bottom contact layer, and the top contact layer together configure a cell contact structure.

Due to a design of the semiconductor device of the present disclosure, junction leakage of the cell contact structure may be reduced by employing the liner layer formed of doped polycrystalline silicon, doped polycrystalline germanium, or doped polycrystalline silicon germanium. Furthermore, sheet resistance of the cell contact structure may be reduced by employing the bottom contact layer and the top contact layer formed of titanium nitride, tungsten, or titanium. As a result, a performance of the semiconductor device is improved.

The foregoing has outlined rather broadly the features and technical advantages of the present disclosure in order that the detailed description of the disclosure that follows may be better understood. Additional features and advantages of the disclosure are described below, and form the subject of the claims of the disclosure. It should be appreciated by those skilled in the art that the conception and specific embodiments disclosed herein may be readily utilized as a basis for modifying or designing other structures or processes for carrying out the purposes of the present disclosure. It should also be realized by those skilled in the art that such equivalent constructions do not depart from the spirit and scope of the disclosure as set forth in the appended claims.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIG. 1 illustrates, in flowchart diagram form, a method for fabricating a semiconductor device in accordance with one embodiment of the present disclosure.

FIG. 2 illustrates, in a schematic top-view diagram, an intermediate semiconductor device in accordance with one embodiment of the present disclosure.

FIG. 3 shows schematic cross-sectional diagrams taken along lines A-A′ and B-B′ in FIG. 2.

FIG. 4 illustrates, in a schematic top-view diagram, an intermediate semiconductor device in accordance with one embodiment of the present disclosure.

FIG. 5 shows schematic cross-sectional diagrams taken along lines A-A′ and B-B′ in FIG. 4.

FIG. 6 illustrates, in a schematic top-view diagram, an intermediate semiconductor device in accordance with one embodiment of the present disclosure.

FIG. 7 shows schematic cross-sectional diagrams taken along lines A-A′ and B-B′ in FIG. 6.

FIG. 8 illustrates, in a schematic top-view diagram, an intermediate semiconductor device in accordance with one embodiment of the present disclosure.

FIG. 9 shows schematic cross-sectional diagrams taken along lines A-A′ and B-B′ in FIG. 8.

FIG. 10 illustrates, in a schematic top-view diagram, an intermediate semiconductor device in accordance with one embodiment of the present disclosure.

FIG. 11 shows schematic cross-sectional diagrams taken along lines A-A′ and B-B′ in FIG. 10.

FIG. 12 illustrates, in a schematic top-view diagram, an intermediate semiconductor device in accordance with one embodiment of the present disclosure.

FIG. 13 shows schematic cross-sectional diagrams taken along lines A-A′ and B-B′ in FIG. 12.

FIG. 14 illustrates, in a schematic top-view diagram, an intermediate semiconductor device in accordance with one embodiment of the present disclosure.

FIG. 15 shows schematic cross-sectional diagrams taken along lines A-A′ and B-B′ in FIG. 14 illustrating part of a process for fabricating the semiconductor device in accordance with one embodiment of the present disclosure.

FIG. 16 shows schematic cross-sectional diagrams taken along lines A-A′ and B-B′ in FIG. 14 illustrating part of a process for fabricating the semiconductor device in accordance with one embodiment of the present disclosure.

FIG. 17 illustrates, in a schematic top-view diagram, an intermediate semiconductor device in accordance with one embodiment of the present disclosure.

FIG. 18 shows schematic cross-sectional diagrams taken along lines A-A′ and B-B′ in FIG. 17.

FIG. 19 illustrates, in a schematic top-view diagram, an intermediate semiconductor device in accordance with one embodiment of the present disclosure.

FIG. 20 shows schematic cross-sectional diagrams taken along lines A-A′ and B-B′ in FIG. 19 illustrating part of a process for fabricating the semiconductor device in accordance with one embodiment of the present disclosure.

FIG. 21 shows schematic cross-sectional diagrams taken along lines A-A′ and B-B′ in FIG. 19 illustrating part of a process for fabricating the semiconductor device in accordance with one embodiment of the present disclosure.

FIG. 22 shows schematic cross-sectional diagrams taken along lines A-A′ and B-B′ in FIG. 19 illustrating part of a process for fabricating the semiconductor device in accordance with one embodiment of the present disclosure.

FIG. 23 shows schematic cross-sectional diagrams taken along lines A-A′ and B-B′ in FIG. 19 illustrating part of a process for fabricating the semiconductor device in accordance with one embodiment of the present disclosure.

FIG. 24 illustrates, in a schematic top-view diagram, an intermediate semiconductor device in accordance with one embodiment of the present disclosure.

FIG. 25 shows schematic cross-sectional diagrams taken along lines A-A′ and B-B′ in FIG. 24 illustrating part of a process for fabricating the semiconductor device in accordance with one embodiment of the present disclosure.

FIG. 26 shows schematic cross-sectional diagrams taken along lines A-A′ and B-B′ in FIG. 24 illustrating part of a process for fabricating the semiconductor device in accordance with one embodiment of the present disclosure.

FIG. 27 illustrates, in a schematic top-view diagram, an intermediate semiconductor device in accordance with one embodiment of the present disclosure.

FIG. 28 shows schematic cross-sectional diagrams taken along lines A-A′ and B-B′ in FIG. 27 illustrating part of a process for fabricating the semiconductor device in accordance with one embodiment of the present disclosure.

FIG. 29 shows schematic cross-sectional diagrams taken along lines A-A′ and B-B′ in FIG. 27 illustrating part of a process for fabricating the semiconductor device in accordance with one embodiment of the present disclosure.

FIG. 30 illustrates, in a schematic top-view diagram, an intermediate semiconductor device in accordance with one embodiment of the present disclosure.

FIG. 31 shows schematic cross-sectional diagrams taken along lines A-A′ and C-C′ in FIG. 30 illustrating part of a process for fabricating the semiconductor device in accordance with one embodiment of the present disclosure.

FIG. 32 shows schematic cross-sectional diagrams taken along lines A-A′ and C-C′ in FIG. 30 illustrating part of a process for fabricating the semiconductor device in accordance with one embodiment of the present disclosure.

FIG. 33 shows schematic cross-sectional diagrams taken along lines A-A′ and C-C′ in FIG. 30 illustrating part of a process for fabricating a semiconductor device in accordance with another embodiment of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features are not in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

It should be understood that when an element or layer is referred to as being “connected to” or “coupled to” another element or layer, it can be directly connected to or coupled to the other element or layer, or intervening elements or layers may be present.

It should be understood that, although the terms first, second, etc. may be used herein to describe various elements, these elements should not be limited by these terms. Unless indicated otherwise, these terms are only used to distinguish one element from another element. Thus, for example, a first element, a first component or a first section discussed below could be termed a second element, a second component or a second section without departing from the teachings of the present disclosure.

Unless the context indicates otherwise, terms such as “same,” “equal,” “planar,” or “coplanar,” as used herein when referring to orientation, layout, location, shapes, sizes, amounts, or other measures, do not necessarily mean an exactly identical orientation, layout, location, shape, size, amount, or other measure, but are intended to encompass nearly identical orientations, layouts, locations, shapes, sizes, amounts, or other measures within acceptable variations that may occur, for example, due to manufacturing processes. The term “substantially” may be used herein to reflect such meaning. For example, items described as “substantially the same,” “substantially equal,” or “substantially planar,” may be exactly the same, equal, or planar, or may be the same, equal, or planar within acceptable variations that may occur, for example, due to manufacturing processes.

In the present disclosure, a semiconductor device generally means a device which can function by utilizing semiconductor characteristics, and an electro-optic device, a light-emitting display device, a semiconductor circuit, and an electronic device are all included in the category of the semiconductor device.

It should be noted that, in the description of the present disclosure, above (or up) corresponds to the direction of the arrow of the direction Z, and below (or down) corresponds to the opposite direction of the arrow of the direction Z.

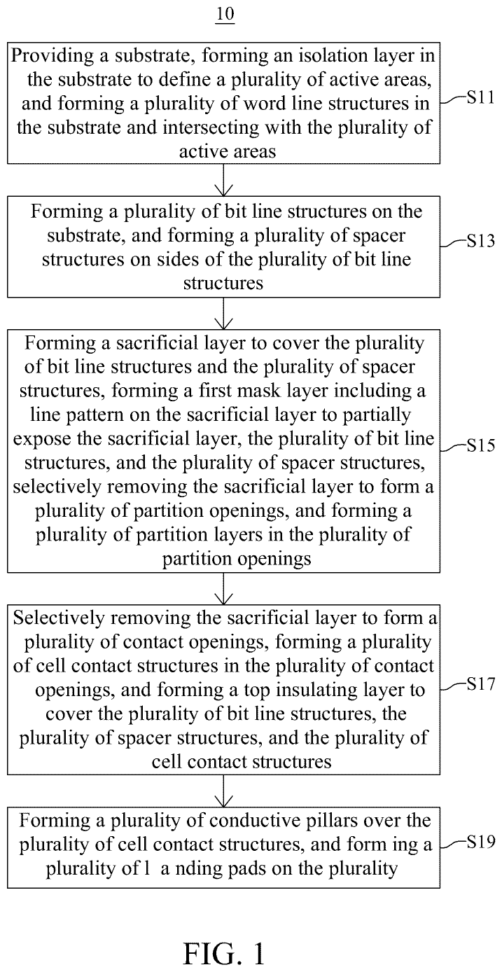

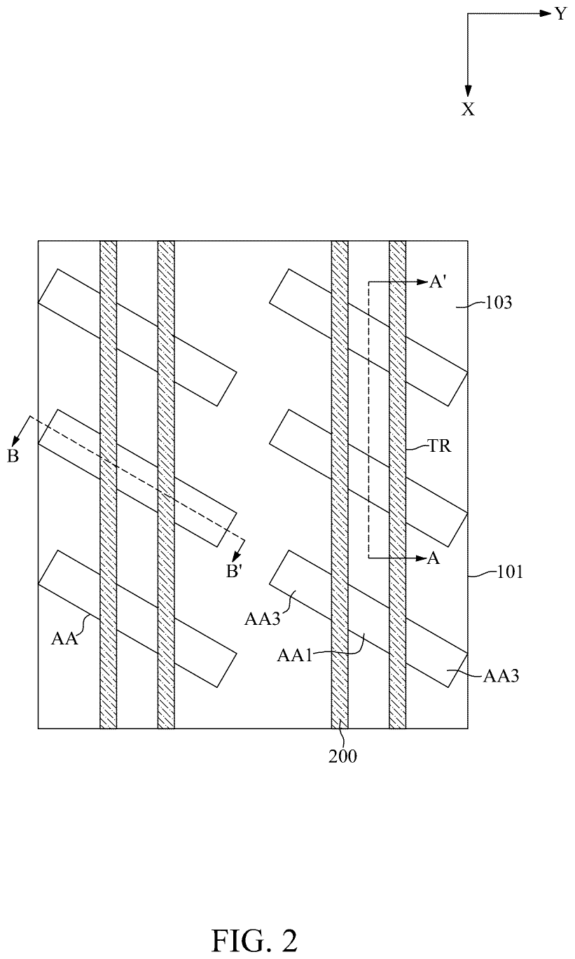

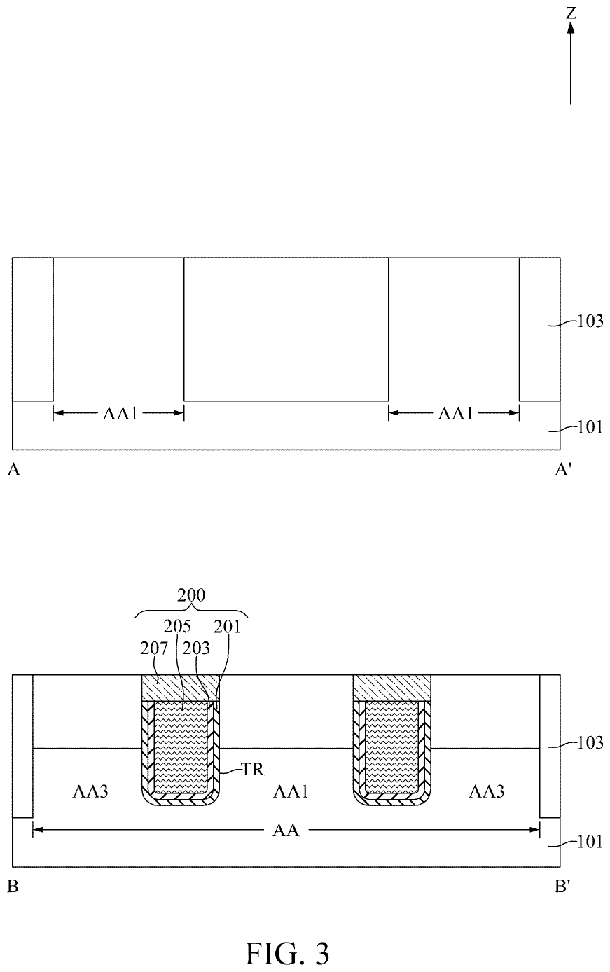

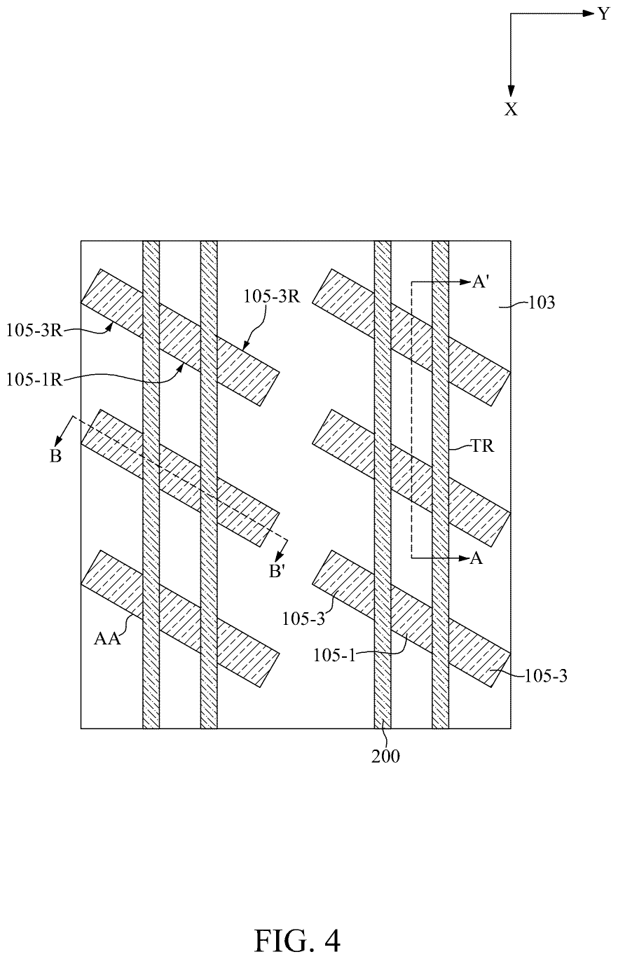

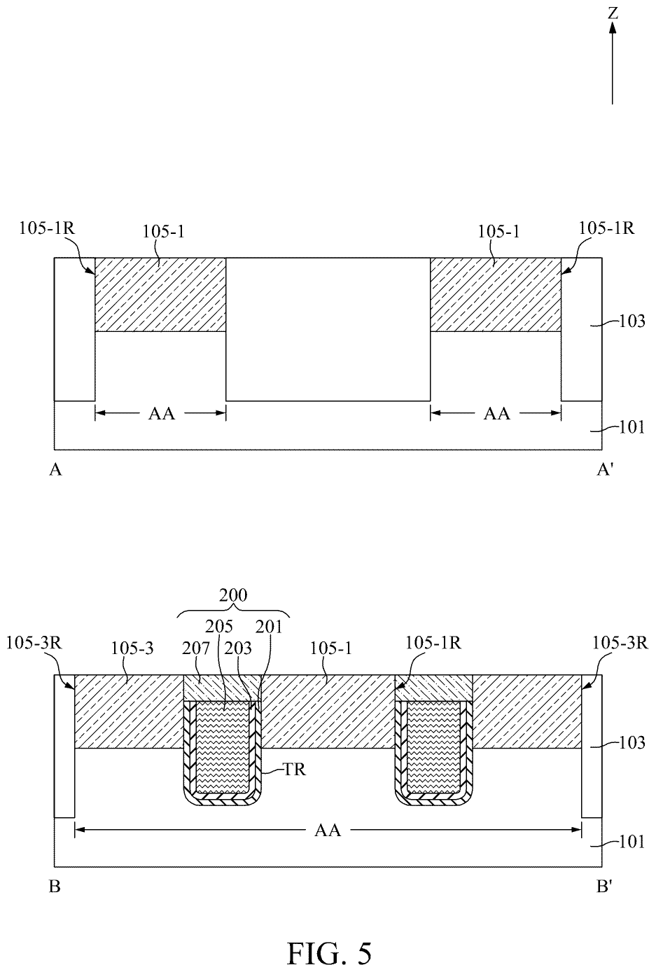

FIG. 1 illustrates, in flowchart diagram form, a method 10 for fabricating a semiconductor device 1A in accordance with one embodiment of the present disclosure. FIG. 2 illustrates, in a schematic top-view diagram, an intermediate semiconductor device in accordance with one embodiment of the present disclosure. FIG. 3 shows schematic cross-sectional diagrams taken along lines A-A′ and B-B′ in FIG. 2. FIG. 4 illustrates, in a schematic top-view diagram, an intermediate semiconductor device in accordance with one embodiment of the present disclosure. FIG. 5 shows schematic cross-sectional diagrams taken along lines A-A′ and B-B′ in FIG. 4.

With reference to FIGS. 1 to 5, in step S11, a substrate 101 may be provided. An isolation layer 103 may be formed within the substrate 101 to define a plurality of active areas AA. A plurality of word line structures 200 may be formed in the substrate 101 to intersect the active areas AA, and a plurality of impurity regions 105-1 and 105-3 may be formed in the active areas AA.

With reference to FIGS. 2 and 3, the substrate 101 may include a bulk semiconductor substrate. The bulk semiconductor substrate may be formed of, for example, an elementary semiconductor, such as silicon or germanium; a compound semiconductor, such as silicon germanium, silicon carbide, gallium arsenide, gallium phosphide, indium phosphide, indium arsenide, indium antimonide, or other III-V compound semiconductor or II-VI compound semiconductor; or a combination thereof.

In some embodiments, the substrate 101 may include a semiconductor-on-insulator structure consisting of, from bottom to top, a handle substrate, an insulator layer, and a topmost semiconductor material layer. The handle substrate and the topmost semiconductor material layer may be formed of a material same as a material of the bulk semiconductor substrate mentioned above. The insulator layer may be a crystalline or non-crystalline dielectric material such as an oxide and/or a nitride. For example, the insulator layer may be a dielectric oxide such as silicon oxide. For another example, the insulator layer may be a dielectric nitride such as silicon nitride or boron nitride. For yet another example, the insulator layer may include a stack of a dielectric oxide and a dielectric nitride such as a stack of, in any order, silicon oxide, silicon nitride, and/or boron nitride. The insulator layer may have a thickness between about 10 nm and about 200 nm. The insulator layer may eliminate leakage current between adjacent elements in the substrate 101 and reduce parasitic capacitance associated with source and drain regions.

It should be noted that the term “about,” when used to modify a quantity of an ingredient, component, or reactant of the present disclosure, refers to variation in a numerical quantity that can occur, for example, through typical measuring and liquid handling procedures used for making concentrates or solutions. Furthermore, variation can occur from inadvertent error in measuring procedures, differences in manufacture, source, or purity of ingredients employed to make compositions or to carry out methods, and the like. In one aspect, the term “about” means within 10% of the reported numerical value. In another aspect, the term “about” means within 5% of the reported numerical value. In yet another aspect, the term “about” means within 10%, 9%, 8%, 7%, 6%, 5%, 4%, 3%, 2% or 1% of the reported numerical value.

With reference to FIGS. 2 and 3, the isolation layer 103 may be formed in the substrate 101. A series of deposition processes may be performed to deposit a pad oxide layer and a pad nitride layer on the substrate 101. A photolithography process and a subsequent etching process, such as an anisotropic dry etching process, may be performed to form trenches penetrating through the pad oxide layer and the pad nitride layer and extending to the substrate 101. An insulating material may be deposited into the trenches and a planarization process, such as chemical mechanical polishing, may be subsequently performed until a top surface of the substrate 101 is exposed to remove excess deposited material, provide a substantially flat surface for subsequent processing steps, and concurrently form the isolation layer 103. The insulating material may be, for example, silicon oxide or another applicable insulating material. The isolation layer 103 may define the plurality of active areas AA in the substrate 101.

It should be noted that, in the description of the present disclosure, a surface of an element (or a feature) located at a highest vertical level along the Z axis is referred to as a top surface of the element (or the feature). A surface of an element (or a feature) located at a lowest vertical level along the Z axis is referred to as a bottom surface of the element (or the feature).

It should be noted that each of the plurality of active areas AA may comprise a portion of the substrate 101 and a space above the portion of the substrate 101. Describing an element as being disposed on the active area AA means that the element is disposed on a top surface of the portion of the substrate 101. Describing an element as being disposed in the active area AA means that the element is disposed in the portion of the substrate 101; however, a top surface of the element may be even with the top surface of the portion of the substrate 101. Describing an element as being disposed above the first area 10 means that the element is disposed above the top surface of the portion of the substrate 101.

In some embodiments, portions of active areas AA may be doped with dopants, respectively. In some embodiments, the doping may be performed using an implantation process. The dopants used in the implantation process may include p-type dopants or n-type dopants. The p-type dopants may be added to an intrinsic semiconductor to create deficiencies of valence electrons. In a silicon-containing substrate, examples of p-type dopants include, but are not limited to, boron, aluminum, gallium, and indium. The n-type dopants may be added to an intrinsic semiconductor to contribute free electrons to the intrinsic semiconductor. In a silicon-containing substrate, examples of n-type dopants include, but are not limited to, antimony, arsenic, and phosphorus. In some embodiments, a dopant concentration of the portions of the active area AA may be between about 1E19 atoms/cm\hat{ }3 and about 1E21 atoms/cm\hat{ }3. After the implantation process, the portions of the active area AA may have an electrical type such as n-type or p-type.

With reference to FIGS. 2 and 3, a plurality of word line trenches TR may be formed in the substrate 101 to define positions of the plurality of word line structures 200. The plurality of word line trenches TR may be formed using a photolithography process followed by a subsequent etching process. From a top-view perspective, the word line trenches TR may have a linear cross-sectional profile, extend along the direction X, and intersect the active areas AA. Furthermore, from a top-view perspective, a pair of word line trenches TR may cross each of the active areas AA and may divide each active area AA into a common active area AA1 and an active area AA3. The common active area AA1 may be positioned between a pair of word line trenches TR, and the active area AA3 may be positioned on opposite sides of the pair of word line trenches TR.

With reference to FIGS. 2 and 3, the plurality of word line structures 200 (e.g., two word line structures 200) may be formed in the plurality of word line trenches TR (e.g., two word line trenches TR), respectively. For brevity, clarity, and convenience of description, only one word line structure 200 is described. The word line structure 200 may include a word line dielectric layer 201, a word line barrier layer 203, a word line conductive layer 205, and a word line capping layer 207.

With reference to FIGS. 2 and 3, the word line dielectric layer 201 may be conformally formed on the inner surface of the word line trench TR. The word line dielectric layer 201 may have a U-shaped cross-sectional profile. In other words, the word line dielectric layer 201 may be inwardly formed in the active area AA. In some embodiments, the word line dielectric layer 201 may be formed using a thermal oxidation process. For example, the word line dielectric layer 201 may be formed through an oxidization process on the inner surface of the word line trench TR. In some embodiments, the word line dielectric layer 201 may be formed using a deposition process such as a chemical vapor deposition or an atomic layer deposition. The word line dielectric layer 201 may include a high-k material, an oxide, a nitride, an oxynitride, or a combination thereof. In some embodiments, after a polysilicon liner layer is deposited, the word line dielectric layer 201 may be formed through a radical oxidation on the polysilicon liner layer. In some embodiments, after the formation of a silicon nitride liner layer, the word line dielectric layer 201 may be formed through a radical oxidation on the silicon nitride liner layer.

In some embodiments, the high-k material may include a hafnium-containing material. The hafnium-containing material may be, for example, hafnium oxide, hafnium silicon oxide, hafnium silicon oxynitride, or a combination thereof. In some embodiments, the high-k material may be, for example, lanthanum oxide, lanthanum aluminum oxide, zirconium oxide, zirconium silicon oxide, zirconium silicon oxynitride, aluminum oxide or a combination thereof.

With reference to FIGS. 2 and 3, the word line barrier layer 203 may be conformally formed on the word line dielectric layer 201 and within the word line trench TR. In some embodiments, the word line barrier layer 203 may be formed of, for example, titanium nitride, titanium, or a combination thereof. In some embodiments, the word line barrier layer 203 may be formed of, for example, titanium nitride. In some embodiments, the word line barrier layer 203 may be formed using, for example, an atomic layer deposition, a physical vapor deposition, a chemical vapor deposition, or another applicable deposition process.

With reference to FIGS. 2 and 3, the word line conductive layer 205 may be formed on the word line barrier layer 203 and within the word line trench TR. In some embodiments, in order to form the word line conductive layer 205, a conductive layer may be formed to fill the word line trench TR, and a recessing process may be subsequently performed. The recessing process may be performed using an etch-back process or sequentially performed using a planarization process and an etch-back process. The word line conductive layer 205 may have a recessed shape that partially fills the word line trench TR. In other words, a top surface of the word line conductive layer 205 may be lower than the top surface of the substrate 101.

In some embodiments, the word line conductive layer 205 may include a metal, a metal nitride, or a combination thereof. For example, the word line conductive layer 205 may be formed of titanium nitride, tungsten, or titanium nitride/tungsten. After the titanium nitride is conformally formed, a titanium nitride/tungsten structure may be formed, wherein the word line trench TR is partially filled using tungsten. Alternatively, either titanium nitride or tungsten may be used exclusively for the word line conductive layer 205. In some embodiments, the word line conductive layer 205 may be formed of, for example, a conductive material such as doped polycrystalline silicon, doped polycrystalline silicon germanium, or a combination thereof. In some embodiments, the word line conductive layer 205 may be formed of, for example, tungsten, aluminum, titanium, copper, the like, or a combination thereof.

With reference to FIGS. 2 and 3, a dielectric material may be deposited using, for example, a chemical vapor deposition, to completely fill the word line trenches TR and covering the top surface of the substrate 101. A planarization process, such as chemical mechanical polishing, may be performed to provide a substantially flat surface for subsequent processing steps and to form the word line capping layer 207. In some embodiments, the word line capping layer 207 may be formed of, for example, silicon nitride, or another applicable dielectric material.

With reference to FIGS. 4 and 5, a plurality of recesses 105-1R and 105-3R may be formed in the substrate 101, and the locations of the recesses 105-1R and 105-3R may be defined by the active areas AA1 and AA3 mentioned above, respectively. In other words, each of the recesses 105-1R may be formed in the active area AA1, while each recess 105-3R may be formed in the active area AA3. It should be noted that, from a top-view perspective, the recess 105-1R may have a contour same as a contour of the active area AA1, and the recess 105-3R may have a contour same as a contour of the active area AA3. In some embodiments, a photolithography process and a subsequent etching process may be performed to remove portions of the substrate 101 and integrally form the plurality of recesses 105-1R and 105-3R.

With reference to FIGS. 4 and 5, an epitaxial growth process may be performed to fill the plurality of recesses 105-1R and the plurality of 105-3R and integrally form the plurality of impurity regions 105-1 and 105-3. The epitaxial growth process may be chemical vapor deposition, atomic layer deposition, or molecular beam epitaxy. In some embodiments, a process temperature of the epitaxial growth process may be between about 700° C. and about 850° C. A process pressure of the epitaxial growth process may be between about 5 Torr to about 50 Torr. In some embodiments, a planarization process, such as chemical mechanical polishing, may be optionally performed to provide a substantially flat surface for subsequent processing steps.

In some embodiments, the plurality of impurity regions 105-1 and 105-3 may be formed of, for example, silicon phosphide (SiP), phosphorus-doped silicon carbon (SiCP), silicon carbide (SiC), silicon germanium (SiGe), silicon-germanium-tin alloy (SiGeSn), silicon-germanium-boron alloy (SiGeB), or another suitable semiconductor material. After the formation of the impurity regions 105-1 and 105-3, the impurity regions 105-1 may serve as common source regions and the impurity regions 105-3 may serve as drain regions.

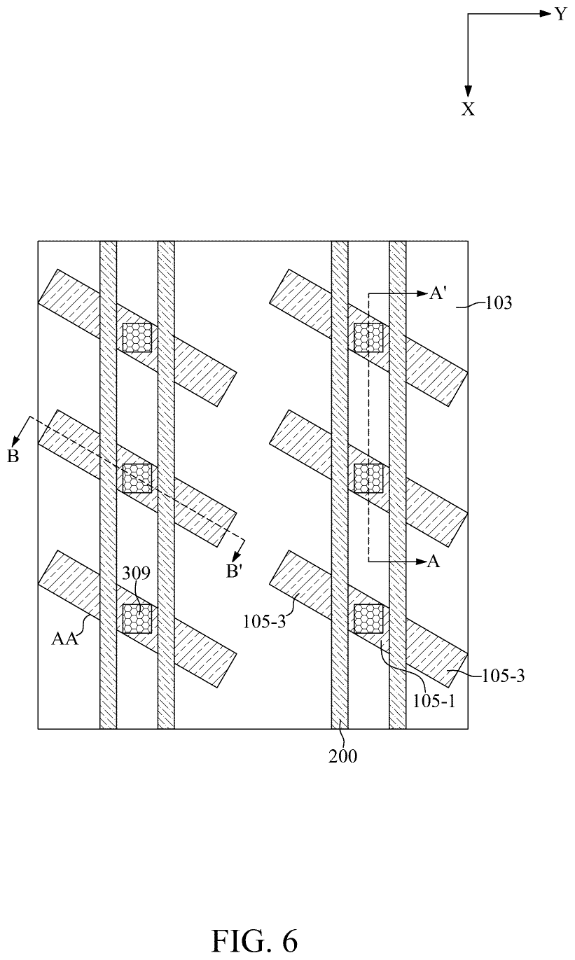

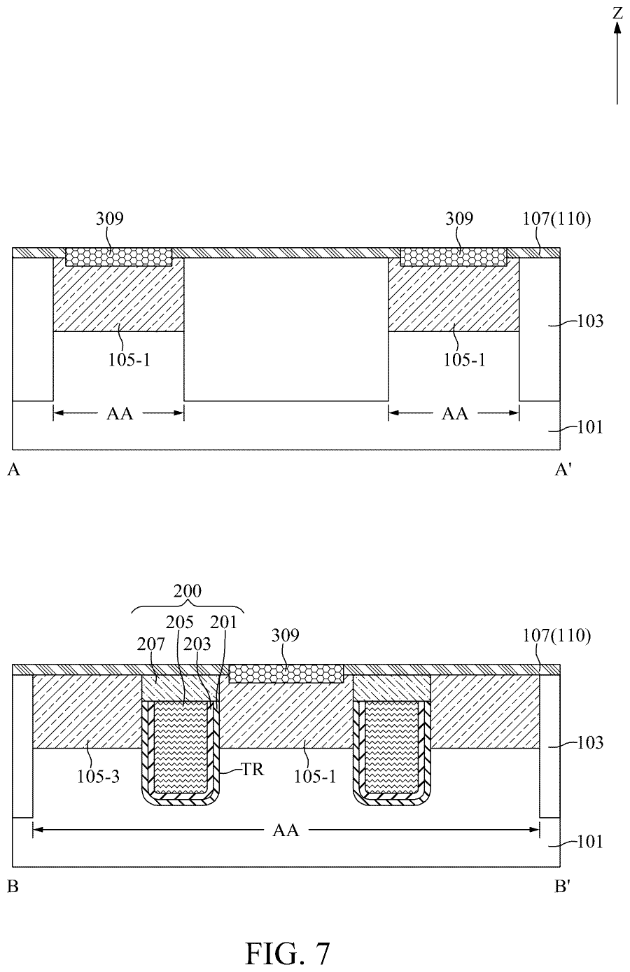

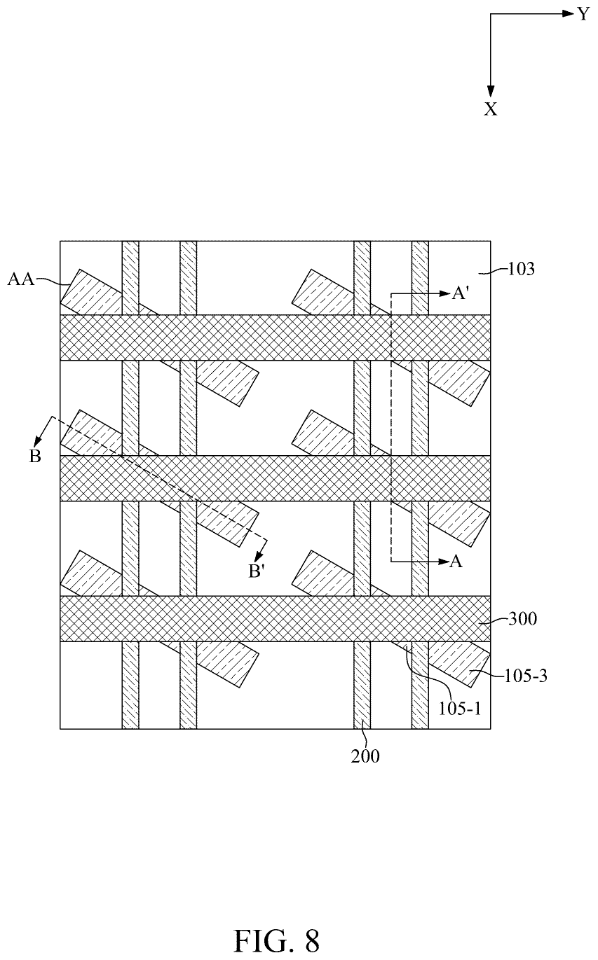

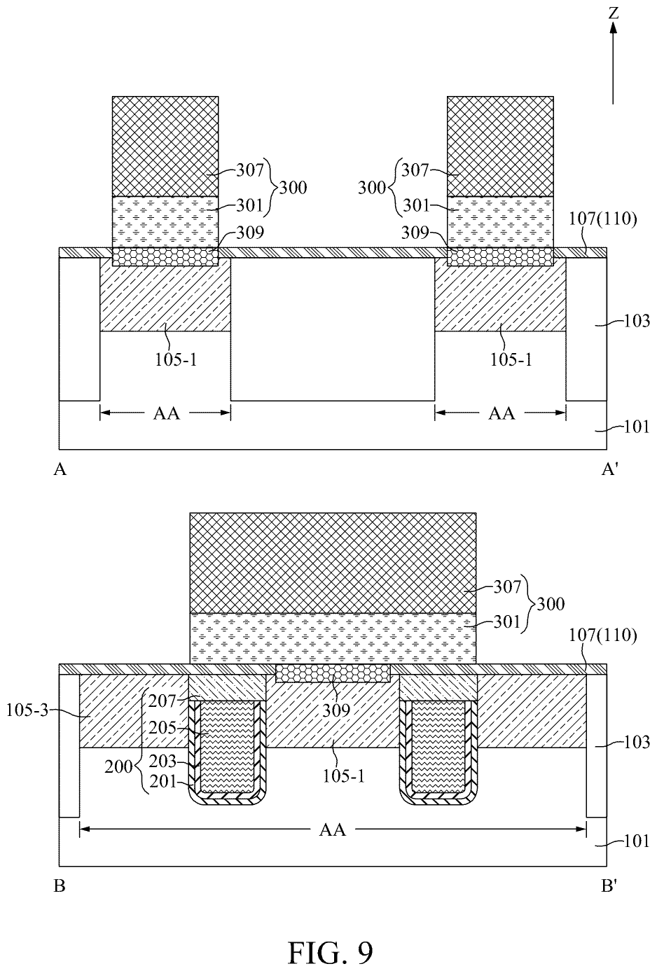

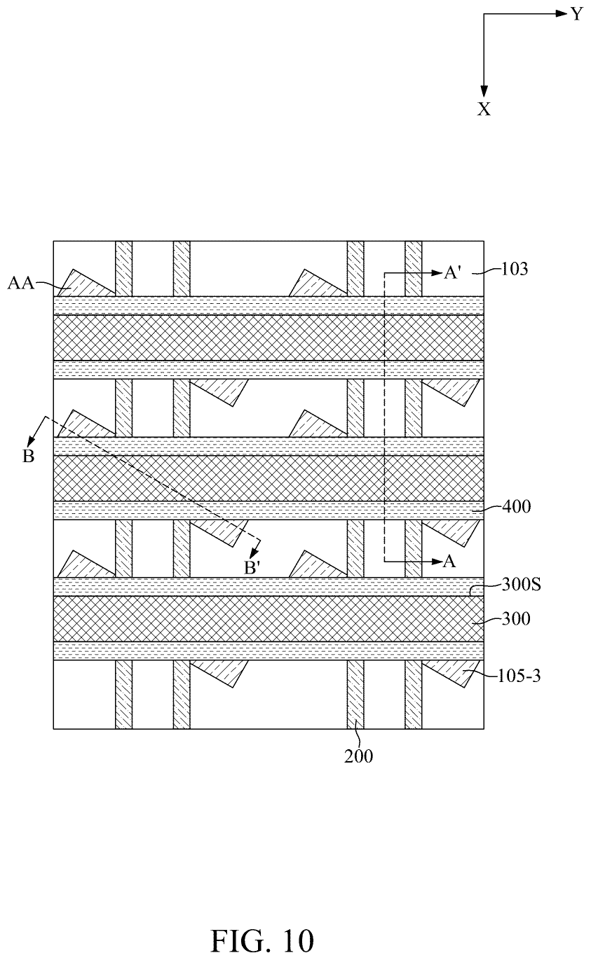

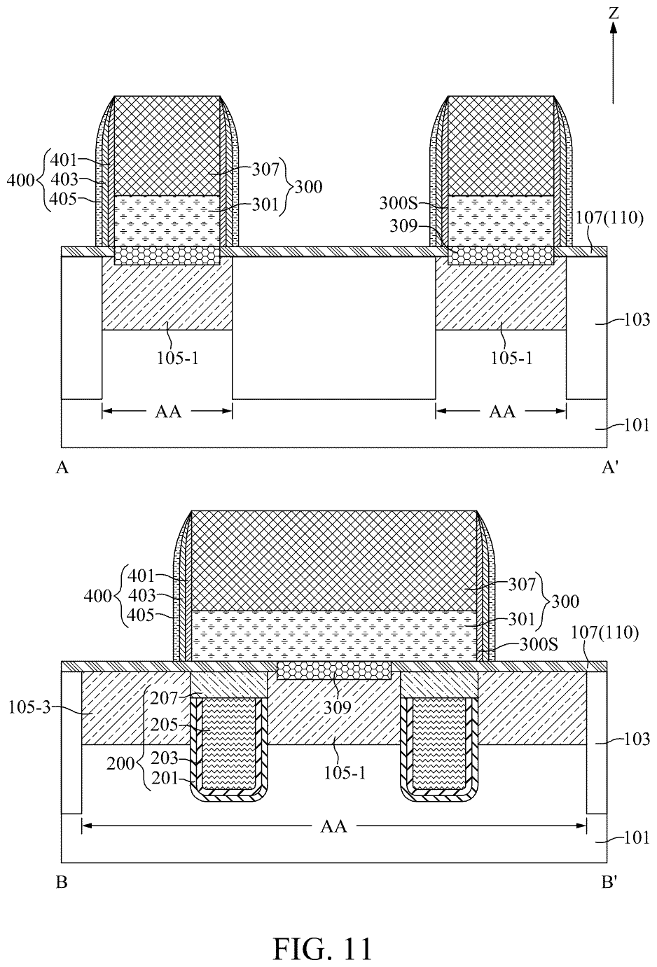

FIG. 6 illustrates, in a schematic top-view diagram, an intermediate semiconductor device in accordance with one embodiment of the present disclosure. FIG. 7 shows schematic cross-sectional diagrams taken along lines A-A′ and B-B′ in FIG. 6. FIG. 8 illustrates, in a schematic top-view diagram, an intermediate semiconductor device in accordance with one embodiment of the present disclosure. FIG. 9 shows schematic cross-sectional diagrams taken along lines A-A′ and B-B′ in FIG. 8. FIG. 10 illustrates, in a schematic top-view diagram, an intermediate semiconductor device in accordance with one embodiment of the present disclosure. FIG. 11 shows schematic cross-sectional diagrams taken along lines A-A′ and B-B′ in FIG. 10. It should be noted that some elements are omitted in top-view diagrams for clarity.

With reference to FIG. 1 and FIGS. 6 to 11, in step S13, a plurality of bit line structures 300 may be formed on the substrate 101, and a plurality of spacer structures 400 may be formed on sides 300S of the plurality of bit line structures 300.

With reference to FIGS. 6 and 7, a bottom dielectric layer 107of a stack of dielectric layers 110 may be formed on the substrate 101. In some embodiments, the bottom dielectric layer 107 may be formed of a material having etching selectivity to the substrate 101 and the isolation layer 103. In some embodiments, the bottom dielectric layer 107 may be formed of, for example, silicon nitride, boron nitride, silicon boron nitride, phosphorus boron nitride, boron carbon silicon nitride, or a combination thereof. In some embodiments, the bottom dielectric layer 107 may be formed of, for example, silicon nitride. In some embodiments, the bottom dielectric layer 107 may be formed using, for example, chemical vapor deposition, plasma-enhanced chemical vapor deposition, or another applicable deposition process.

With reference to FIGS. 6 and 7, a plurality of bit line contacts 309 may be formed, penetrating the bottom dielectric layer 107 and extending to the plurality of common source regions 105-1, respectively. In some embodiments, the plurality of bit line contacts 309 may be formed of, for example, tungsten, cobalt, zirconium, tantalum, titanium, aluminum, ruthenium, copper, and metal carbide (e.g., tantalum carbide, titanium carbide, tantalum magnesium carbide), metal nitride (e.g., titanium nitride) and transition metal aluminide, or a combination thereof. In some embodiments, from a top-view perspective, the plurality of bit line contacts 309 may have a square-shaped cross-sectional profile, but are not limited thereto. In some embodiments, the plurality of bit line contacts 309 may have a rectangular-shaped, a circular-shaped, or another applicable cross-sectional profile.

With reference to FIGS. 8 and 9, the plurality of bit line structures 300 may be formed on the bottom dielectric layer 107 and electrically connected to the plurality of bit line contacts 309. From a top-view perspective, the plurality of bit line structures 300 may extend along a direction Y and be separated from each other. In other words, from a top-view perspective, the plurality of bit line structures 300 may intersect the plurality of word line structures 200. For brevity, clarity, and convenience of description, only one bit line structure 300 is described. In some embodiments, the bit line structure 300 may include a bit line top conductive layer 301 and a bit line capping layer 307.

The bit line top conductive layer 301 may be formed on the bit line contact 309 and electrically connected to the bit line contact 309. In some embodiments, the bit line top conductive layer 301 may be formed of, for example, titanium nitride, tungsten, titanium, nickel, platinum, tantalum, cobalt, silver, copper, aluminum, another applicable conductive material, or a combination thereof. The bit line capping layer 307 may be formed on the bit line top conductive layer 301. In some embodiments, the bit line capping layer 307 may be formed of, for example, silicon nitride or another applicable insulating material.

With reference to FIGS. 10 and 11, the plurality of spacer structures 400 may be formed on the sides 300S of the plurality of bit line structures 300. In other words, from a top-view perspective, the plurality of spacer structures 400 may extend along the direction Y. For brevity, clarity, and convenience of description, only one spacer structure 400 is described. In some embodiments, the spacer structure 400 may include a bit line inner spacer 401, a bit line middle spacer 403, and a bit line outer spacer 405.

The bit line inner spacer 401 may be formed on the side 300S of the bit line structure 300. In some embodiments, the bit line inner spacer 401 may be formed of a material same as a material of the bit line capping layer 307. In some embodiments, the bit line inner spacer 401 may be formed of, for example, silicon nitride or another applicable insulating material. In some embodiments, the bit line inner spacer 401 may be formed using conformally depositing a layer of insulating material over the bottom dielectric layer 107 and a subsequent anisotropic etching process.

The bit line middle spacer 403 may be conformally formed on the bit line inner spacer 401. In some embodiments, the bit line middle spacer 403 may be formed of, for example, silicon oxide or another applicable insulating oxide. In some embodiments, the bit line middle spacer 403 may be formed using conformally depositing a layer of insulating oxide over the bottom dielectric layer 107 and a subsequent anisotropic etching process.

The bit line outer spacer 405 may be conformally formed on the bit line middle spacer 403. In some embodiments, the bit line outer spacer 405 may be formed of a material same as a material of the bit line inner spacer 401 or the bit line capping layer 307. In some embodiments, the bit line outer spacer 405 may be formed of, for example, silicon nitride or another applicable insulating material. In some embodiments, the bit line outer spacer 405 may be formed using conformally depositing a layer of insulating material over the bottom dielectric layer 107 and a subsequent anisotropic etching process.

In some embodiments, the bit line inner spacer 401 may be optional. In other words, the bit line middle spacer 403 may be directly formed on the side 300S of the bit line structure 300.

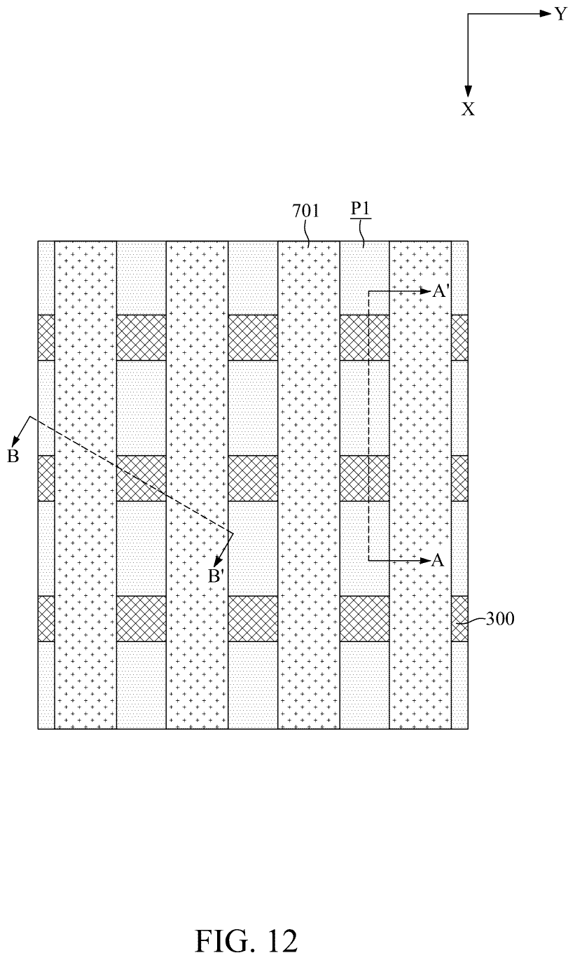

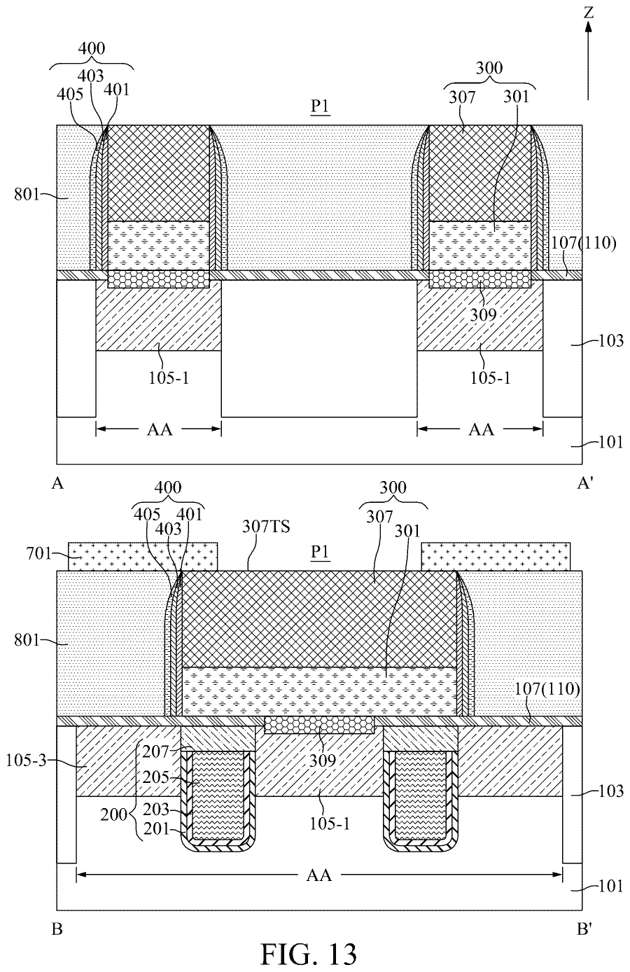

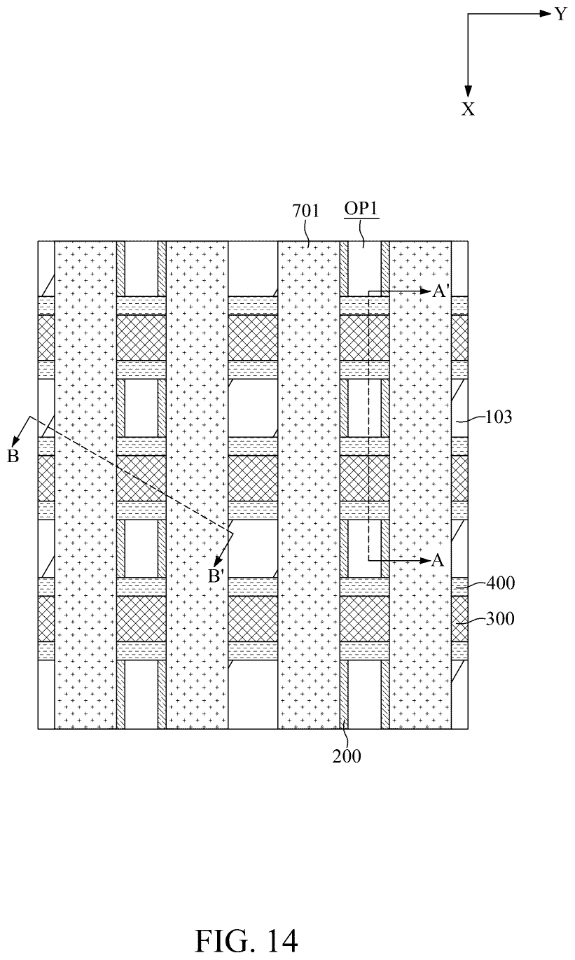

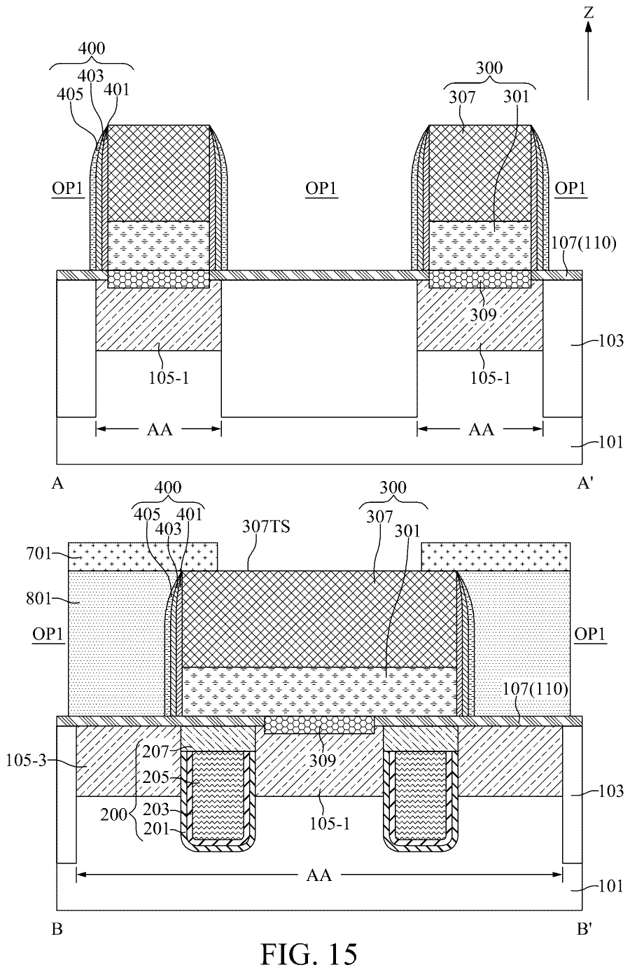

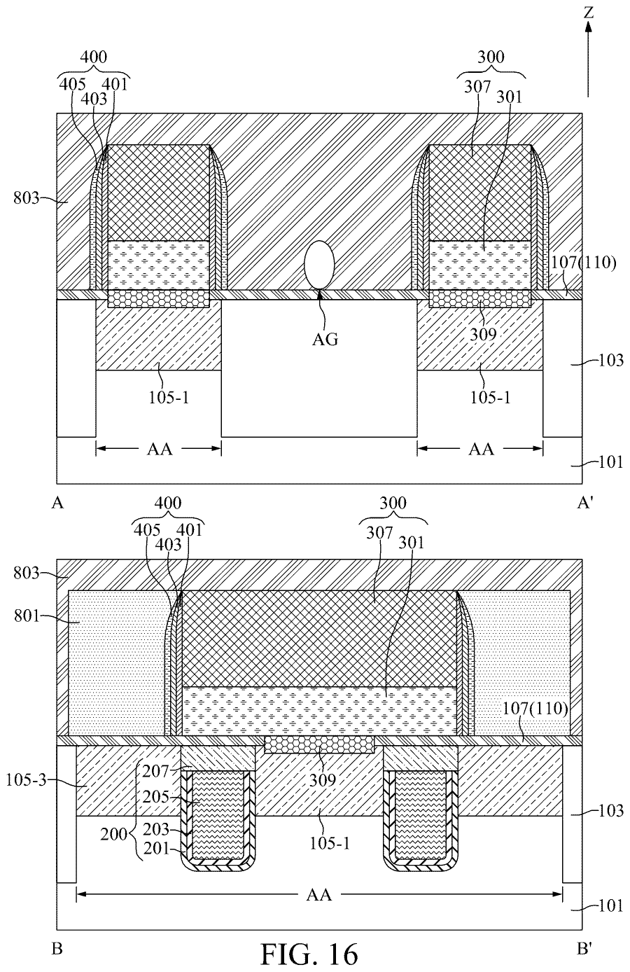

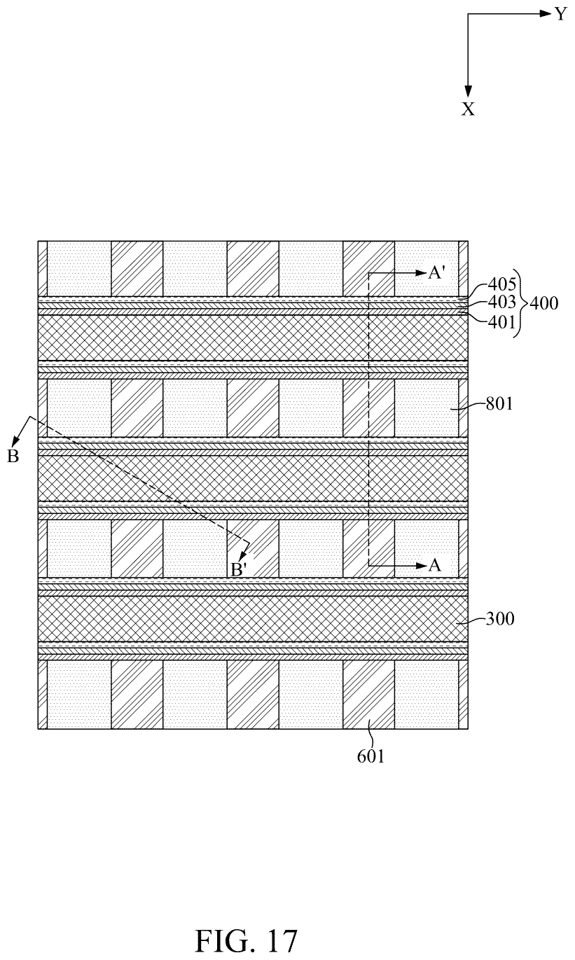

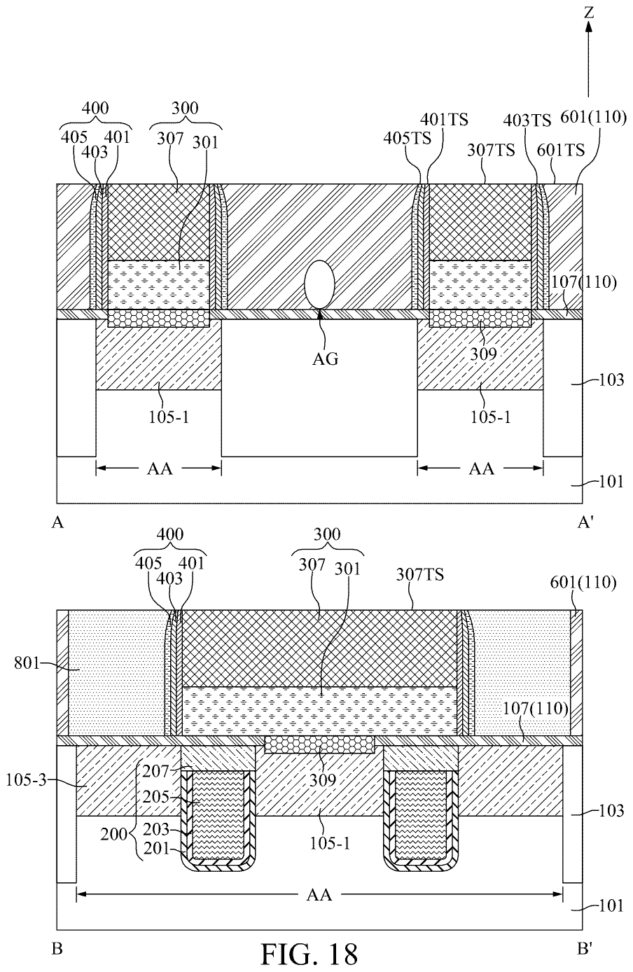

FIG. 12 illustrates, in a schematic top-view diagram, an intermediate semiconductor device in accordance with one embodiment of the present disclosure. FIG. 13 shows schematic cross-sectional diagrams taken along lines A-A′ and B-B′ in FIG. 12. FIG. 14 illustrates, in a schematic top-view diagram, an intermediate semiconductor device in accordance with one embodiment of the present disclosure. Each of FIGS. 15 and 16 shows schematic cross-sectional diagrams taken along lines A-A′ and B-B′ in FIG. 14 illustrating part of a process for fabricating the semiconductor device 1A in accordance with one embodiment of the present disclosure. FIG. 17 illustrates, in a schematic top-view diagram, an intermediate semiconductor device in accordance with one embodiment of the present disclosure. FIG. 18 shows schematic cross-sectional diagrams taken along lines A-A′ and B-B′ in FIG. 17.

With reference to FIG. 1 and FIGS. 12 to 18, in step S15, a sacrificial layer 801 may be formed to cover the plurality of bit line structures 300 and the plurality of spacer structures 400, a first mask layer 701 including a line pattern P1 may be formed on the sacrificial layer 801 to partially expose the sacrificial layer 801, the plurality of bit line structures 300, and the plurality of spacer structures 400. The sacrificial layer 801 may be selectively removed to form a plurality of partition openings OP1, and a plurality of partition layers 601 may be formed in the plurality of partition openings OP1.

With reference to FIGS. 12 and 13, the sacrificial layer 801 may be formed over the bottom dielectric layer 107 to cover the plurality of bit line structures 300 and the plurality of spacer structures 400. In some embodiments, the sacrificial layer 801 may be formed of, for example, a material having etching selectivity to the bit line outer spacer 405 or the bit line capping layer 307. In some embodiments, the sacrificial layer 801 may be formed of, for example, silicon oxynitride, silicon nitride oxide, or another applicable material. In some embodiments, the sacrificial layer 801 may be formed using, for example, chemical vapor deposition, plasma-enhanced chemical vapor deposition, or another applicable deposition process. In some embodiments, a planarization process, such as chemical mechanical polishing, may be performed until top surfaces 307TS of the plurality of bit line structures 300 are exposed to remove excess material and provide a substantially flat surface for subsequent processing steps.

It should be noted that, in the description of the present disclosure, silicon oxynitride refers to a substance which contains silicon, nitrogen, and oxygen and in which a proportion of oxygen is greater than that of nitrogen. Silicon nitride oxide refers to a substance which contains silicon, oxygen, and nitrogen and in which a proportion of nitrogen is greater than that of oxygen.

With reference to FIGS. 12 and 13, the first mask layer 701 may be formed on the sacrificial layer 801. In some embodiments, the first mask layer 701 may be a photoresist layer. From a top-view perspective, the line pattern P1 of the first mask layer 701 may include multiple rectangular-shaped spaces extending along the direction X. and arranged alternatively along the direction Y. Through these spaces, the sacrificial layer 801, the plurality of bit line structures 300, and the plurality of spacer structures 400 may be partially exposed.

With reference to FIGS. 14 and 15, the sacrificial layer 801 that is exposed through the line pattern P1 of the first mask layer 701 may be selectively removed. In some embodiments, the removal of the sacrificial layer 801 may be achieved through an anisotropic etching process, such as an anisotropic dry etching process. After the removal of the sacrificial layer 801, the plurality of partition openings OP1 may be formed in the locations where the sacrificial layer 801 was exposed through the line pattern P1 of the first mask layer 701. The first mask layer 701 may then be removed following the formation of these partition openings OP1.

With reference to FIG. 16, a layer of partition material 803 may be formed over the sacrificial layer 801 to completely fill the plurality of partition openings OP1. In some embodiments, the partition material 803 may be a material having etching selectivity to the sacrificial layer 801. In some embodiments, the partition material 803 may have a material same as a material of the bit line capping layer 307 or the bit line outer spacer 405. In some embodiments, the partition material 803 may be, for example, silicon nitride or another applicable insulating material. In some embodiments, the layer of partition material 803 may be formed of, for example, chemical vapor deposition or other applicable deposition processes.

In some embodiments, from a cross-sectional perspective, a plurality of air gaps AG may be sealed in the layer of partition material 803, alternating with bit line structure 300. Specifically, the air gaps AG may be formed at a bottom of the layer of the partition material 803. During the deposition of the layer of partition material 803, the air gaps AG may be created by a variant deposition rate of the deposition process. For example, a slower deposition rate is used at the beginning of the deposition process, followed by a faster deposition rate. This approach allows the upper portions of the partition openings OP1 to be filled sooner than the lower portions of the partition openings OP1. As a result, the air gaps AG are formed in the layer of partition material 803. As deposition conditions and other parameters vary, the air gaps AG may be formed in different shapes.

With reference to FIGS. 17 and 18, a planarization process, such as chemical mechanical polishing, may be performed to remove excess material, provide a substantially flat surface for subsequent processing steps, and turn the layer of partition material 803 into a plurality of partition layers 601. The partition layers 601 may be formed or stacked on the bottom dielectric layer 107 and are a layer of the stack of dielectric layers 110. From a top-view perspective, each of the plurality of partition layers 601 may have a linear-shaped (or rectangular-shaped) cross-sectional profile extending along the direction X. The plurality of partition layers 601 may be arranged alternatively along the direction X, with each corresponding bit line structure 300 situated between two adjacent partition layers 601. Along the direction Y, the plurality of partition layers 601 may be arranged alternatively with the sacrificial layer 801 interposed therebetween. From a top-view perspective, arrangement of the plurality of partition layers 601 and the plurality of bit line structures 300 may divide the sacrificial layer 801 into multiple segments.

For brevity, clarity, and convenience of description, only one partition layer 601 is described. In some embodiments, after the planarization process, the bit line inner spacer 401, the bit line middle spacer 403, and the bit line outer spacer 405 may be exposed. The top surface 601TS of the partition layer 601, the top surface 401TS of the bit line inner spacer 401, the top surface 403TS of the bit line middle spacer 403, the top surface 405TS of the bit line outer spacer 405, the top surface 307TS of the bit line capping layer 307 may be substantially coplanar.

In some embodiments, the bit line inner spacer 401 and the bit line middle spacer 403 may be covered by the bit line outer spacer 405 after the planarization process. In such embodiments, the top surface 405TS of the bit line outer spacer 405, the top surface 307TS of the bit line capping layer 307 may be substantially coplanar.

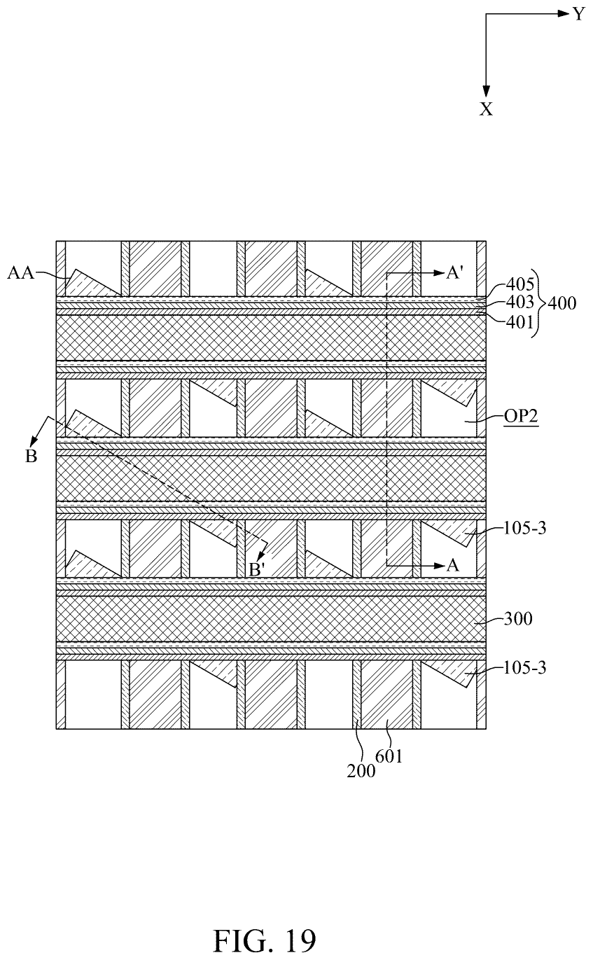

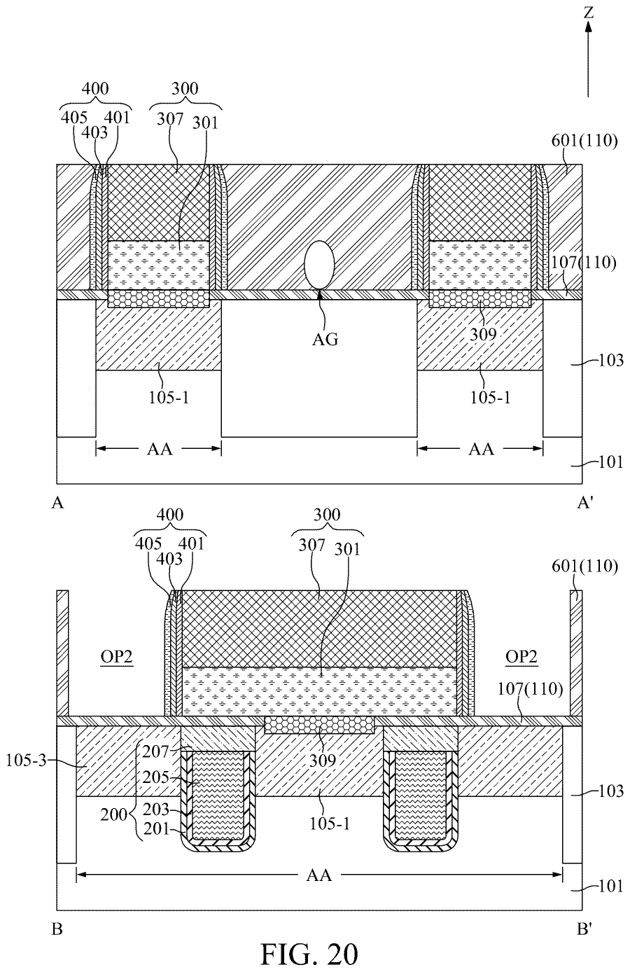

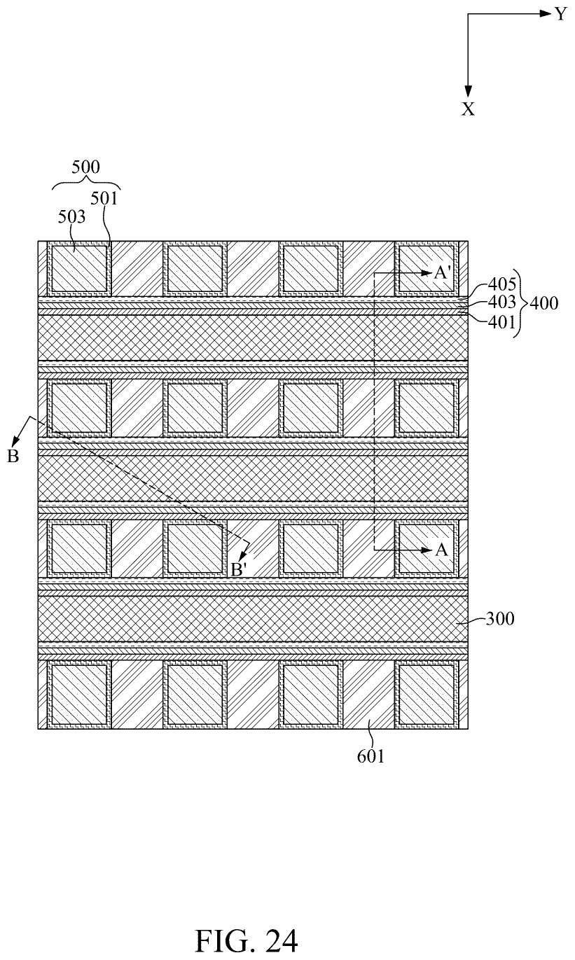

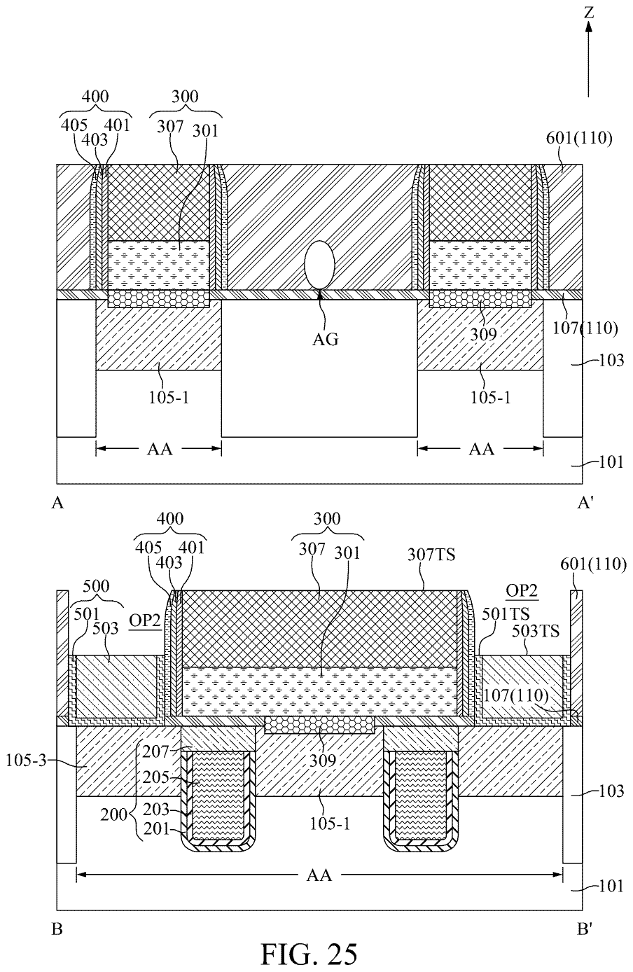

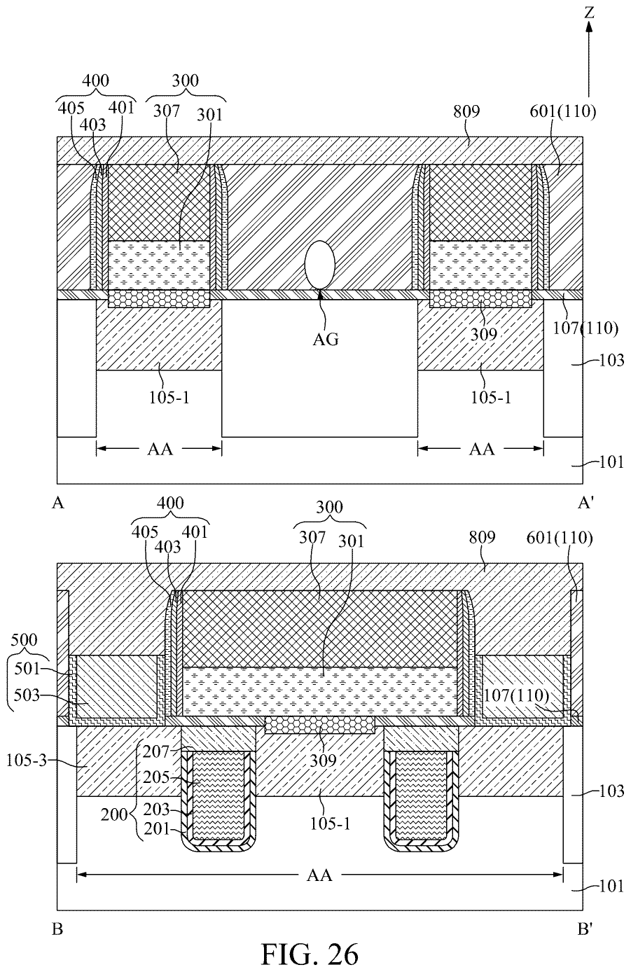

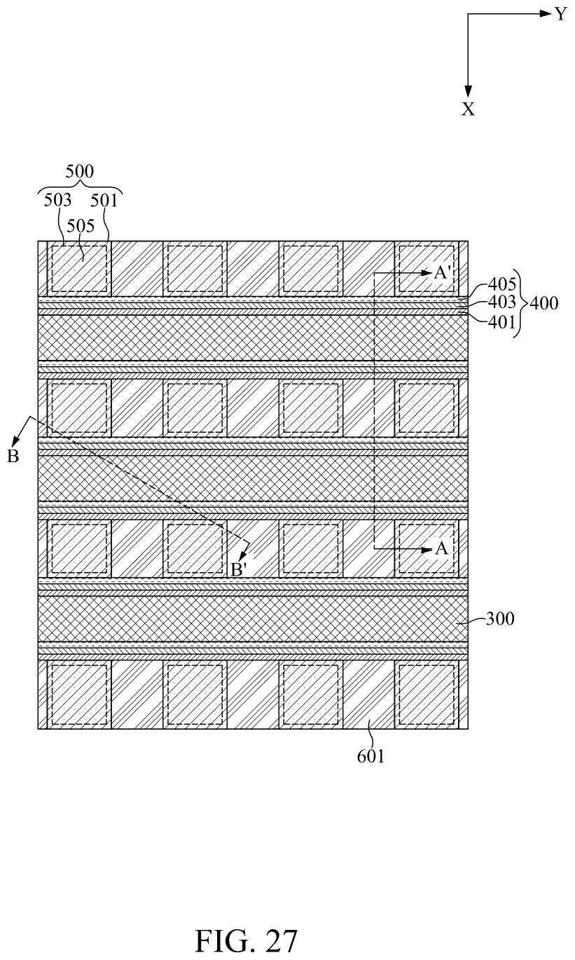

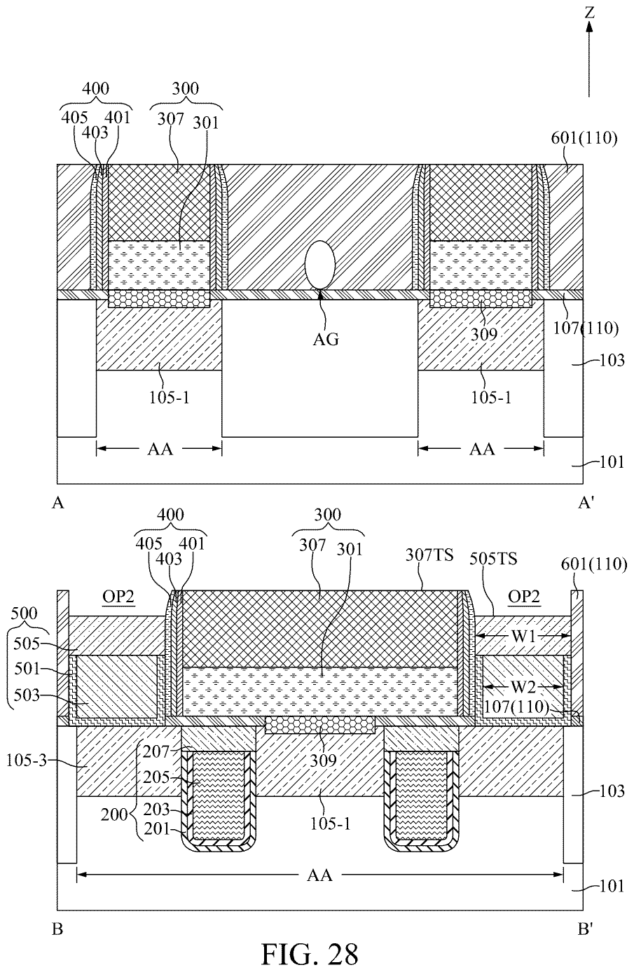

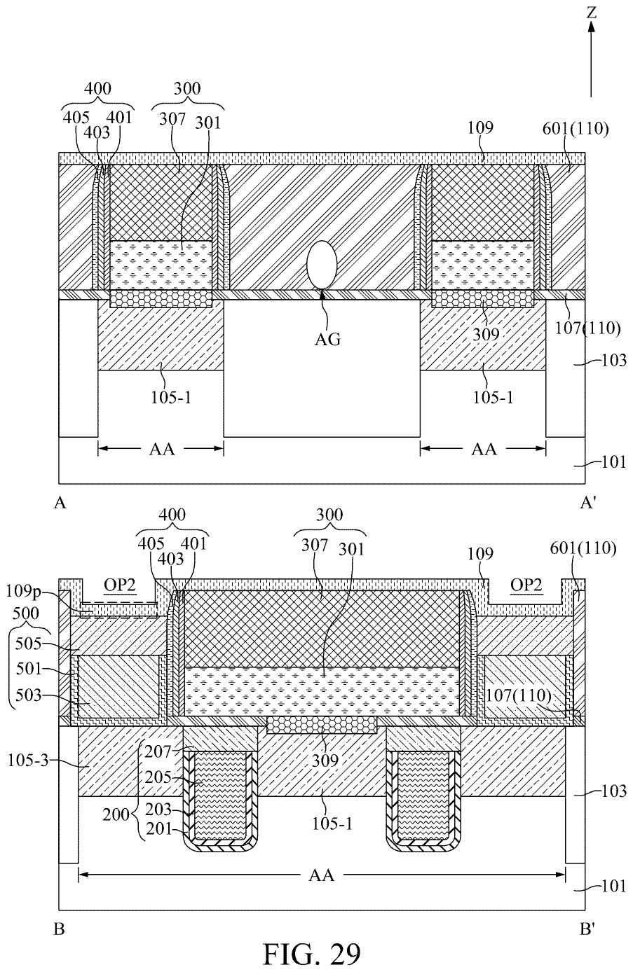

FIG. 19 illustrates, in a schematic top-view diagram, an intermediate semiconductor device in accordance with one embodiment of the present disclosure. Each of FIGS. 20 to 23 shows cross-sectional diagrams taken along lines A-A′ and B-B′ in FIG. 19 illustrating part of a process for fabricating the semiconductor device 1A in accordance with one embodiment of the present disclosure. FIG. 24 illustrates, in a schematic top-view diagram, an intermediate semiconductor device in accordance with one embodiment of the present disclosure. Each of FIGS. 25 and 26 shows schematic cross-sectional diagrams taken along lines A-A′ and B-B′ in FIG. 24 illustrating part of a process for fabricating the semiconductor device 1A in accordance with one embodiment of the present disclosure. FIG. 27 illustrates, in a schematic top-view diagram, an intermediate semiconductor device in accordance with one embodiment of the present disclosure. Each of FIGS. 28 and 29 shows schematic cross-sectional diagrams taken along lines A-A′ and B-B′ in FIG. 27 illustrating part of a process for fabricating the semiconductor device 1A in accordance with one embodiment of the present disclosure.

With reference to FIG. 1 and FIGS. 19 to 29, in step S17, the sacrificial layer 801 may be selectively removed to form a plurality of contact openings OP2, a plurality of cell contact structures 500 may be formed in the plurality of contact openings OP2, and a top insulating layer 109 may be formed to cover the plurality of bit line structures 300, the plurality of spacer structures 400, and the plurality of cell contact structures 500.

With reference to FIGS. 19 and 20, the sacrificial layer 801 may be selectively removed by an etching process. For example, the removal of the sacrificial layer 801 may be achieved through an anisotropic etching process. After the removal of the sacrificial layer 801, the plurality of contact openings OP2 may be formed in the locations where the sacrificial layer 801 was previously present in multiple segments. For brevity, clarity, and convenience of description, only one contact opening OP2 is described. From a cross-sectional perspective, the contact opening OP2 may be disposed on the bottom dielectric layer 107. From a top-view perspective, the contact opening OP2 may be enclosed by two adjacent partition layers 601 along the direction Y and two adjacent bit line structures 300 (or the spacer structures 400 disposing on the sides 300S of the two adjacent bit line structures 300) along the direction X.

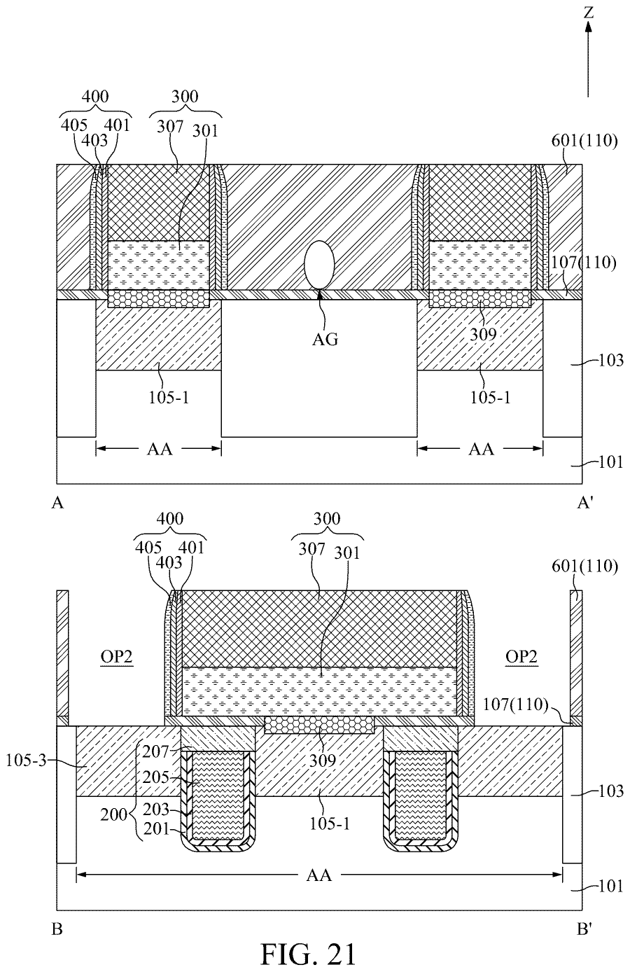

With reference to FIG. 21, a punch-through etching process may be performed to remove portions of the bottom dielectric layer 107 that exposes through the plurality of contact openings OP2. In some embodiments, the punch-through etching process may be an anisotropic dry etching process. The punch-through etching process may extend the plurality of contact openings OP2 downward to the substrate 101. After the punch-through etching process, the plurality of drain regions 105-3 may be exposed through the plurality of contact openings OP2.

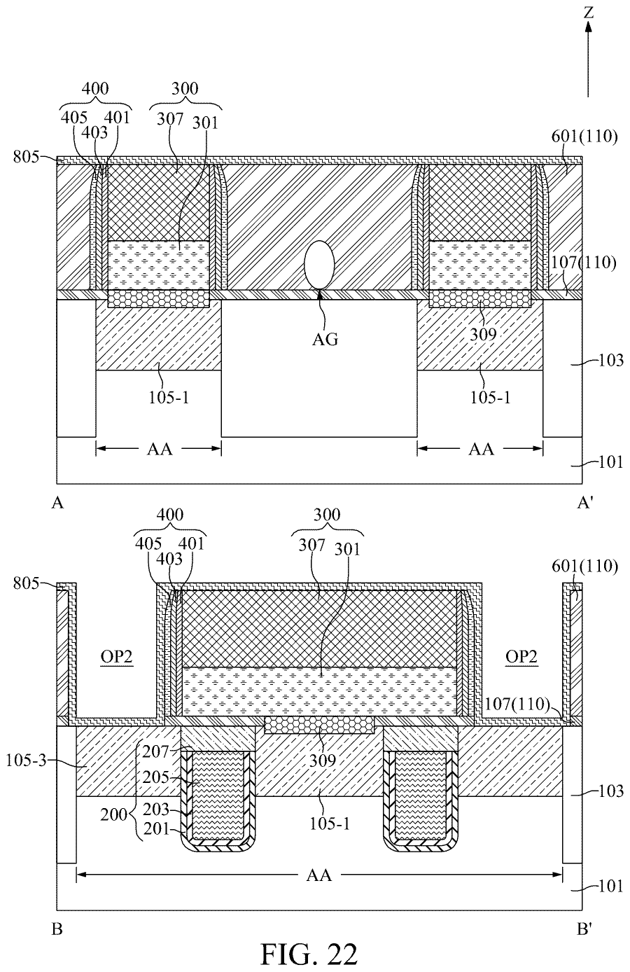

With reference to FIG. 22, a layer of liner material 805 may be conformally formed to cover the substrate 101, the plurality of bit line structures 300, the plurality of spacer structures 400, and the plurality of partition layers 601. In some embodiments, the liner material 805 may be, for example, doped polycrystalline silicon, doped polycrystalline germanium, or doped polycrystalline silicon germanium. In some embodiments, the liner material 805 may include p-type dopants or n-type dopants. In some embodiments, the layer of liner material 805 may be formed by, for example, atomic layer deposition, chemical vapor deposition, or other applicable deposition processes.

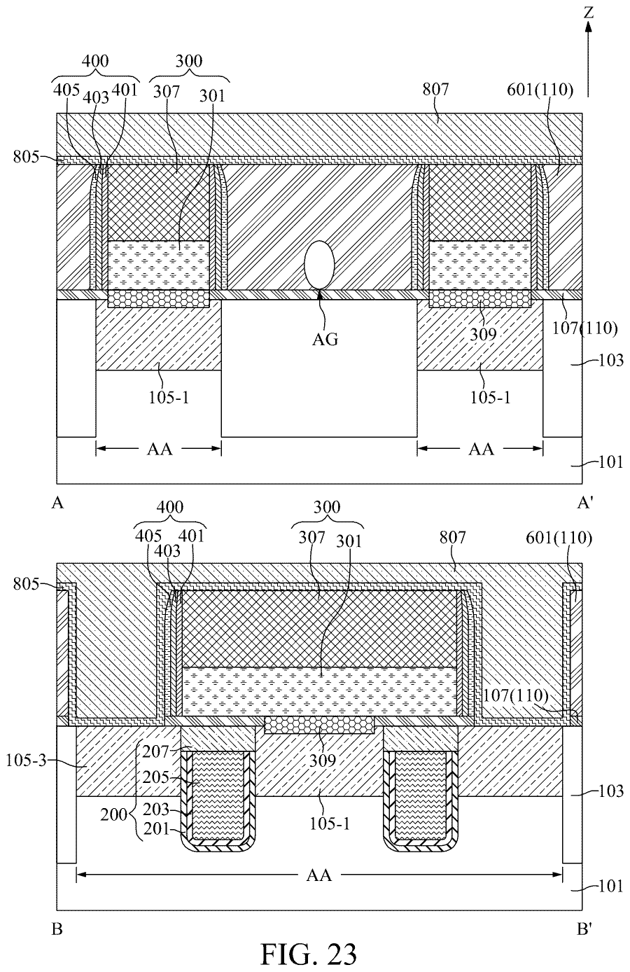

With reference to FIG. 23, a layer of first conductive material 807 may be formed on the layer of liner material 805 and may completely fill the plurality of contact openings OP2. In some embodiments, the first conductive material 807 may be a material with good electrical conductivity (or a material having electrical conductivity better than polycrystalline silicon, polycrystalline germanium, or polycrystalline silicon germanium). In some embodiments, the first conductive material 807 may be, for example, tungsten, cobalt, zirconium, tantalum, titanium, aluminum, ruthenium, copper, metal carbide (e.g., tantalum carbide, titanium carbide, tantalum magnesium carbide), metal nitride (e.g., titanium nitride), transition metal aluminide, or a combination thereof. In some embodiments, the first conductive material 807 may be, for example, titanium nitride, titanium, tungsten, or a combination thereof.

With reference to FIGS. 24 and 25, an etch-back process may be performed to remove portions of the liner material 805 and the first conductive material 807. After the etch-back process, the remaining portions of the liner material 805 may be turned into a plurality of liner layers 501 within the plurality of contact openings OP2. The remaining portions of the first conductive material 807 may be turned into a plurality of bottom contact layers 503 within the plurality of contact openings OP2.

For brevity, clarity, and convenience of description, only one liner layer 501 and one bottom contact layer 503 are described. In some embodiments, from a cross-sectional perspective, the top surface 503TS of the bottom contact layer 503 and the top surface 501TS of the liner layer 501 may be substantially coplanar. The top surface 503TS of the bottom contact layer 503 and the top surface 501TS of the liner layer 501 may be lower than the top surface 307TS of the bit line capping layer 307 (i.e., the top surface of the bit line structure 300). In some embodiments, from a top-view perspective, the liner layer 501 may have a square-ring-shaped or rectangular-ring-shaped cross-sectional profile. The bottom contact layer 503 may have a square-shaped or rectangular cross-sectional profile.

With reference to FIG. 26, a layer of second conductive material 809 may be formed over the substrate 101 to completely fill the plurality of contact openings OP2 and cover the plurality of partition layers 601, the plurality of bit line structures 300, and the plurality of spacer structures 400. In some embodiments, the second conductive material 809 may be, for example, a material with good electrical conductivity (or a material having electrical conductivity better than polycrystalline silicon, polycrystalline germanium, or polycrystalline silicon germanium). In some embodiments, the second conductive material 809 may have a material same as a material of the bottom contact layer 503. In some embodiments, the second conductive material 809 may be, for example, tungsten, cobalt, zirconium, tantalum, titanium, aluminum, ruthenium, copper, metal carbide (e.g., tantalum carbide, titanium carbide, tantalum magnesium carbide), metal nitride (e.g., titanium nitride), transition metal aluminide, or a combination thereof. In some embodiments, the second conductive material 809 may be, for example, titanium nitride, titanium, tungsten, or a combination thereof.

With reference to FIGS. 27 and 28, an etch-back process may be performed to remove portions of the second conductive material 809. After the etch-back process, the remaining portions of the second conductive material 809 may be turned into a plurality of top contact layer 505 within the plurality of contact openings OP2. For brevity, clarity, and convenience of description, only one top contact layer 505 is described. In some embodiments, from a cross-sectional perspective, the top surface 505TS of the top contact layer 505 may be lower than the top surface 307TS of the bit line capping layer 307. In some embodiments, the width W1 of the top contact layer 505 may be greater than the width W2 of the bottom contact layer 503. In some embodiments, from a top-view perspective, the top contact layer 505 may have a square-shaped or rectangular-shaped cross-sectional profile. The liner layer 501, the bottom contact layer 503, and the top contact layer 505 together configure the cell contact structure 500. The cell contact structure 500 may electrically connect to the corresponding drain region 105-3.

With reference to FIG. 29, the top insulating layer 109 may be formed over the substrate 101 to cover the plurality of partition layers 601, the plurality of cell contact structures 500, the plurality of spacer structures 400, and the plurality of bit line structures 300. In some embodiments, the top insulating layer 109 may be formed of a material same as a material of the bit line capping layer 307. In some embodiments, the top insulating layer 109 may be formed of, for example, silicon nitride or another applicable insulating material. After the formation of the top insulating layer 109, a bottom portion 109p of the top insulating layer 109 within the contact opening OP2 and on the contact structure 500 may be removed. The removal of the bottom portion 109p may be performed using an anisotropic etching process, such as a dry etching process.

The utilization of the liner layer 501 formed of doped polycrystalline silicon, doped polycrystalline germanium, or doped polycrystalline silicon germanium, may serve to reduce the junction leakage in the cell contact structure 500. Additionally, the employment of the bottom contact layer 503 and the top contact layer 505 made from materials such as titanium nitride, tungsten, or titanium, may effectively lower the sheet resistance of the cell contact structure 500. These enhancements collectively may improve a performance of the semiconductor device 1A.

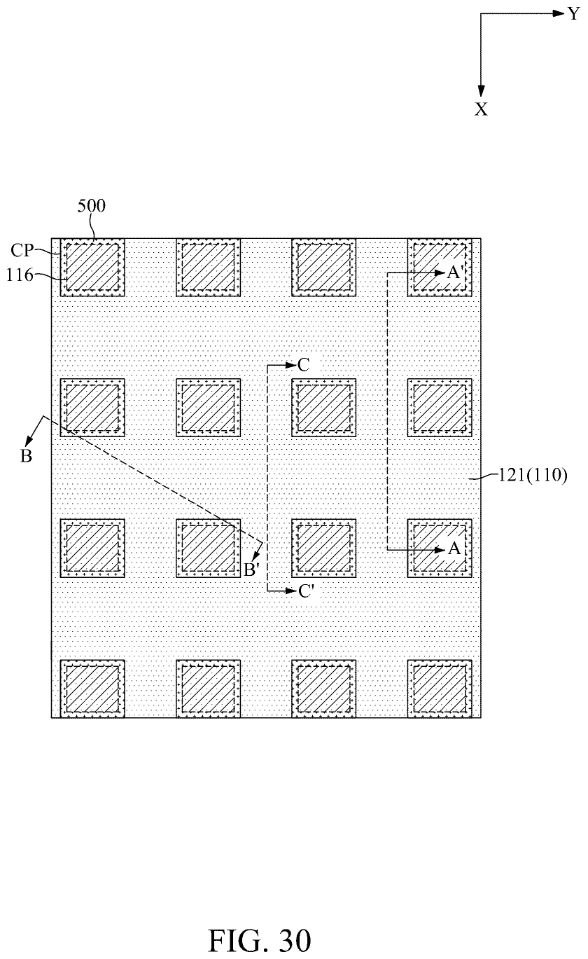

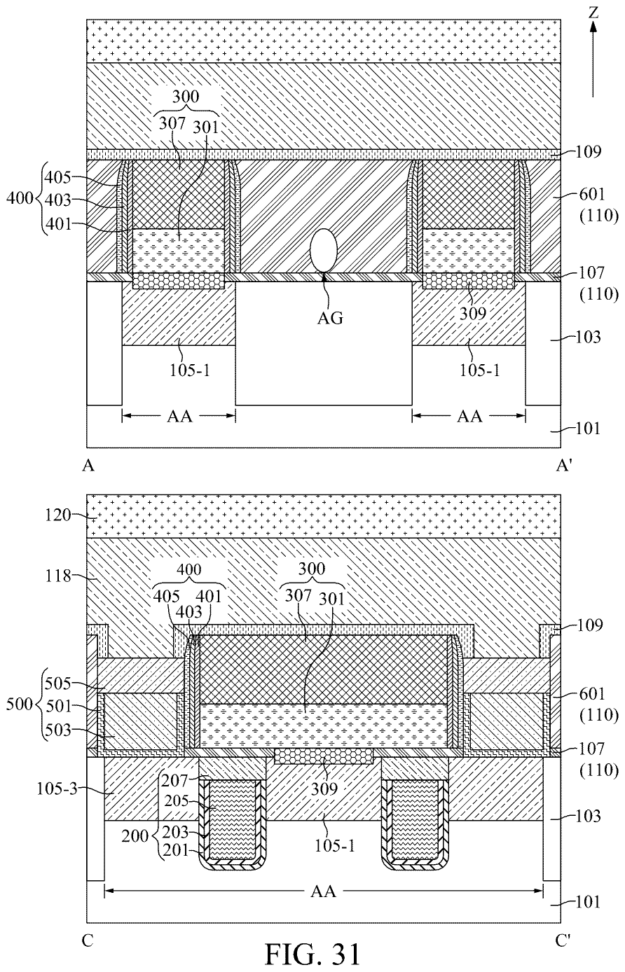

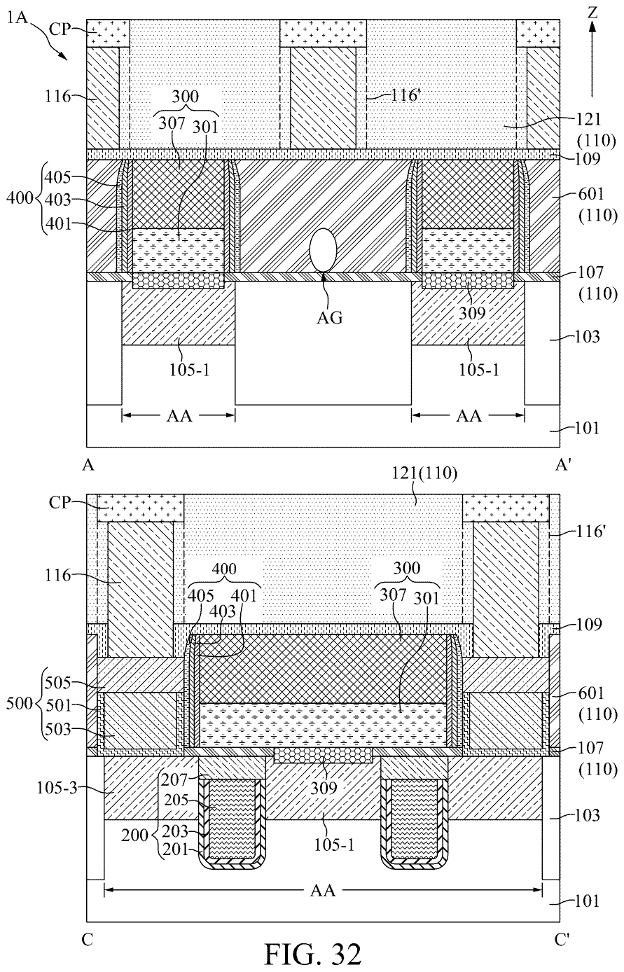

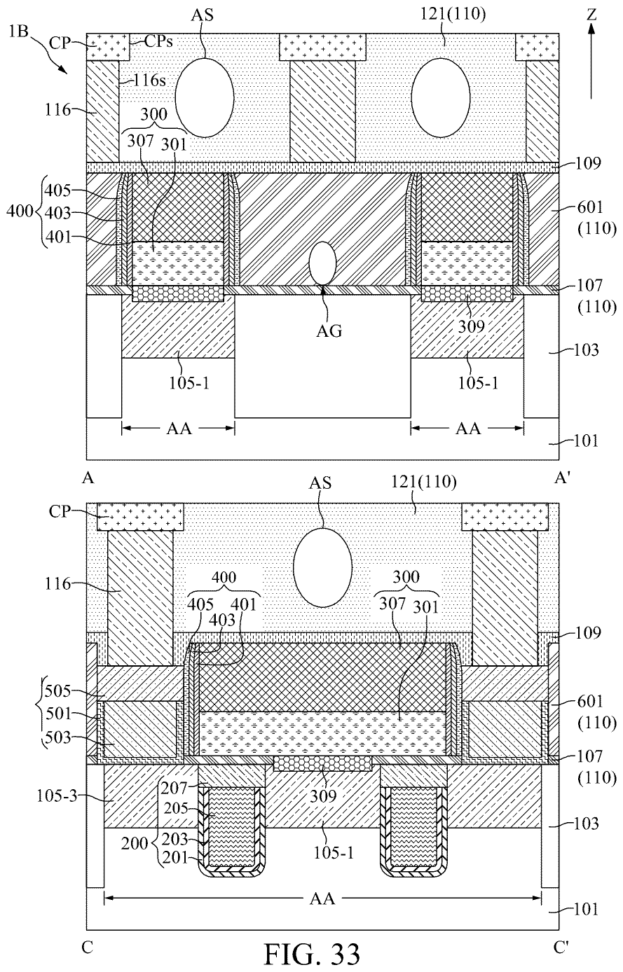

FIG. 30 illustrates, in a schematic top-view diagram, an intermediate semiconductor device in accordance with one embodiment of the present disclosure. Each of FIGS. 31 and 32 shows schematic cross-sectional diagrams taken along lines A-A′ and C-C′ in FIG. 30 illustrating part of a process for fabricating the semiconductor device 1A in accordance with one embodiment of the present. FIG. 33 shows schematic cross-sectional diagrams taken along lines A-A′ and C-C′ in FIG. 30 illustrating part of a process for fabricating a semiconductor device 1B in accordance with another embodiment of the present.

With reference to FIG. 1 and FIGS. 30 to 32, in step S19, a plurality of conductive pillars 116 may be formed over the cell contact structures 500, and a plurality of landing pads CP may be formed on the conductive pillars 116, respectively.

With reference to FIGS. 30 and 31, a first and a second conductive layers 118 and 120 are globally formed on the top insulating layer 109. The second conductive layer 120 is stacked on the first conductive layer 118. It should be noted that the contact openings OP2 may be simultaneously filled with the first conductive layer 118. The conductive pillars 116 and the landing pads CP will be formed by patterning the first and second conductive layers 118 and 120 in the following steps. In some embodiments, the first conductive layer 118 may have a thickness greater than that of the second conductive layer 120. In addition, in some embodiments, a conductive material for forming the second conductive layer 120 has a resistivity lower than that of the first conductive layer 118, and a conductive material for forming the first conductive layer 118 has sufficient etching selectivity with respect to that of the second conductive layer 120. The formation of the conductive layers 118 and 120 may include a deposition process (e.g., a PVD process), a plating process, or a combination thereof.

With reference to FIG. 32, the first and second conductive layers 118 and 120 are patterned to form initial conductive pillars 116′ and the landing pads CP. During the patterning, portions of the first and second conductive layers 118 and 120 are removed, exposing portions of the current topmost dielectric layer (e.g., dielectric layer 109) may be exposed. Sidewalls of the formed initial conductive pillars 116′ may be substantially coplanar with sidewalls of the formed landing pads CP. In other words, a footprint area of each initial conductive pillar 116′ may be substantially identical with a footprint area of the overlying landing pad CP. The conductive pillars 116 may be formed by laterally recessing the initial conductive pillars 116′ in the following step. In some embodiments, the formation of the initial conductive pillars 116′ and the landing pads CP may include a lithography process and a single etching process (e.g., a single anisotropic etching process). In such embodiments, the first and second conductive layers 118 and 120 are partially removed in the same etching process. In alternative embodiments, the formation of the initial conductive pillars 116′ and the landing pads CP uses two etching processes (e.g., two anisotropic etching processes). A first etching process is performed for forming the landing pads CP, followed by a second etching process for forming the initial conductive pillars 116′.

Subsequently, the initial conductive pillars 116′ are laterally recessed, so as to form the conductive pillars 116. In some embodiments, a method for lateral recessing the initial conductive pillars 116′ includes an isotropic etching process (e.g., a wet etching process). In those embodiments where the conductive material for forming the landing pads CP has a sufficient etching selectivity with respect to the conductive material for forming the initial conductive pillars 116′, the landing pads CP may avoid from being damaged (or may be slightly consumed) during such isotropic etching process. As a result, the formed conductive pillars 116 can be laterally recessed with respect to the landing pads CP. It should be noted that, as shown in FIG. 30, the plurality of conductive pillars 116 and the landing pads CP have a square-shaped cross-sectional profile, but are not limited thereto. In some embodiments, the plurality of conductive pillars 116 and the landing pads CP may have a rectangular-shaped, a circular-shaped, or another applicable cross-sectional profile.

The conductive pillars 116 and the landing pads CP form stacking structures T over cell contact structures 500, and define recesses in between. A dielectric layer 121 of the stack of dielectric layers 110 is filled in the recesses defined by the stacking structures T. In some embodiments, a thickness of the dielectric layer 121 is greater than thicknesses of the other dielectric layers in the stack of dielectric layers 110 (e.g., the bottom dielectric layer 107 and the partition layer 601). In some embodiments, the formation of the dielectric layer 121 includes a deposition process (e.g., a CVD process), and may further include a planarization process for removing excess material above the landing pads CP. After the dielectric layer 121 is formed surrounding the stacking structures T, the semiconductor device 1A is obtained.

FIG. 33 shows schematic cross-sectional diagrams taken along lines A-A′ and C-C′ in FIG. 30 illustrating part of a process for fabricating the semiconductor device 1B in accordance with another embodiment of the present disclosure. Elements in FIG. 33 that are same as or similar to elements in FIG. 32 are marked with similar reference numbers and duplicative descriptions are omitted.

With reference to FIG. 33, in some embodiments, the dielectric layer 121 may not completely fill up the recesses between the stacking structures T. Since the conductive pillars 116 are laterally recessed from the landing pads CP, a space between adjacent landing pads CP is shorter than a space between adjacent conductive pillars 116. In other words, the recesses defined between the stacking structures T respectively have a relatively narrow top portion and a relatively wide bottom portion. When the dielectric layer 121 is filled in those narrow recesses, the relatively narrow top portions of these recesses may be sealed before the relatively wide bottom portions of these recesses could be completely filled. As a result, the air gaps AS may be formed in these relatively wide bottom portions. In other words, the possibly formed air gaps AS are located between the conductive pillars 116. As dimensions of the recesses, deposition conditions, and other parameters vary, the air gaps AS may be formed in different shapes, and top ends of the air gaps AS may or may not extend over top ends of the conductive pillars 116. In some embodiments, the air gaps AS may not expose sidewalls of the conductive pillars 116.

One aspect of the present disclosure provides a semiconductor device comprising a substrate having a plurality of impurity regions; two bit line structures formed on the substrate, extending along a first direction, and separated from each other; two partition layers positioned on the substrate, extending along a second direction perpendicular to the first direction, separated from each other along the first direction, and simultaneously contacting the two bit line structures; and a cell contact structure disposed over the substrate. The cell contact structure comprises a bottom contact layer positioned on the substrate and enclosed by the two bit line structures and the two partition layers. The cell contact structure also comprises a liner layer positioned between the substrate and the bottom contact layer, between the two bit line structures and the bottom contact layer, and between the two partition layer and the bottom contact layer. The cell contact structure further comprises a top contact layer positioned on the liner layer and the bottom contact layer. The two bit line structures comprise an air gap disposed therebetween.

Another aspect of the present disclosure provides a semiconductor device comprising a substrate; a plurality of impurity regions disposed in the substrate; two bit line structures formed on the substrate, extending along a first direction, and separated from each other; two partition layers positioned on the substrate, extending along a second direction perpendicular to the first direction, separated from each other along the first direction, and simultaneously contacting the two bit line structures; a cell contact structure disposed over the substrate; a conductive pillar positioned on the cell contact structure; a landing pad disposed on the conductive pillar; and a stack of dielectric layers disposed on the substrate and comprising at least one dielectric layers. The two bit line structures comprise a first air gap disposed therebetween. The cell contact structure comprises a bottom contact layer positioned on the substrate and enclosed by the two bit line structures and the two partition layers. The cell contact structure also comprises a liner layer positioned between the substrate and the bottom contact layer, between the two bit line structures and the bottom contact layer, and between the two partition layer and the bottom contact layer. The cell contact structure further comprises a top contact layer positioned on the liner layer and the bottom contact layer. The plurality of impurity regions are formed of silicon phosphide, phosphorus-doped silicon carbon, silicon carbide, silicon germanium, silicon-germanium-tin alloy, or silicon-germanium-boron alloy. A sidewall of the conductive pillar is laterally recessed from a sidewall of the landing pad. A dielectric layer of the stack of dielectric layers is configured as a thicker dielectric layer laterally surrounding the conductive pillars and the landing pad. A plurality of second air gaps are sealed in the thicker dielectric layer and alternating with the conductive pillars.

Another aspect of the present disclosure provides a method for fabricating a semiconductor device including providing a substrate; forming two bit line structures on the substrate, extending along a first direction, and separated from each other; forming a plurality of spacer structures on sides of the two bit line structures; forming an air gap between the two bit line structures; forming two partition layers on the substrate, extending along a second direction perpendicular to the first direction, separated from each other, and resulting in a contact opening in conjunction with the plurality of spacer structures; conformally forming a liner layer in the contact opening and within the contact opening; forming a bottom contact layer on the liner layer and within the contact opening; and forming a top contact layer on the liner layer, on the bottom contact layer, and within the contact opening. The liner layer, the bottom contact layer, and the top contact layer together configure a cell contact structure.

Another aspect of the present disclosure provides a method for fabricating a semiconductor device including providing a substrate with a plurality of active area; forming a plurality of impurity regions in the substrate; forming two bit line structures on the substrate, extending along a first direction, and separated from each other; forming a plurality of spacer structures on sides of the two bit line structures; forming a first air gap between the two bit line structures; forming two partition layers on the substrate, extending along a second direction perpendicular to the first direction, separated from each other, and resulting in a contact opening in conjunction with the plurality of spacer structures; conformally forming a liner layer in the contact opening and within the contact opening; forming a bottom contact layer on the liner layer and within the contact opening; and forming a top contact layer on the liner layer, on the bottom contact layer, and within the contact opening. The plurality of impurity regions are formed of silicon phosphide, phosphorus-doped silicon carbon, silicon carbide, silicon germanium, silicon-germanium-tin alloy, or silicon-germanium-boron alloy. The liner layer, the bottom contact layer, and the top contact layer together configure a cell contact structure.

Due to a design of the semiconductor device of the present disclosure, junction leakage of the cell contact structure 500 may be reduced by employing the liner layer 501 formed of doped polycrystalline silicon, doped polycrystalline germanium, or doped polycrystalline silicon germanium. In addition, sheet resistance of the cell contact structure 500 may be reduced by employing the bottom contact layer 503 and the top contact layer 505 formed of titanium nitride, tungsten, or titanium. As a result, a performance of the semiconductor device 1A may be improved.

Although the present disclosure and its advantages have been described in detail, it should be understood that various changes, substitutions and alterations can be made herein without departing from the spirit and scope of the disclosure as defined by the appended claims. For example, many of the processes discussed above can be implemented in different methodologies and replaced by other processes, or a combination thereof.

Moreover, the scope of the present application is not intended to be limited to the particular embodiments of the process, machine, manufacture, composition of matter, means, methods and steps described in the specification. As one of ordinary skill in the art will readily appreciate from the disclosure of the present disclosure, processes, machines, manufacture, compositions of matter, means, methods, or steps, presently existing or later to be developed, that perform substantially the same function or achieve substantially the same result as the corresponding embodiments described herein may be utilized according to the present disclosure. Accordingly, the appended claims are intended to include within their scope such processes, machines, manufacture, compositions of matter, means, methods, and steps.

What is claimed is:

1. A semiconductor device, comprising:
a substrate having a plurality of impurity regions;
two bit line structures formed on the substrate, extending along a first direction, and separated from each other;
two partition layers positioned on the substrate, extending along a second direction perpendicular to the first direction, separated from each other along the first direction, and simultaneously contacting the two bit line structures; and
a cell contact structure disposed over the substrate, comprising:
a bottom contact layer positioned on the substrate and enclosed by the two bit line structures and the two partition layers;
a liner layer positioned between the substrate and the bottom contact layer, between the two bit line structures and the bottom contact layer, and between the two partition layer and the bottom contact layer; and
a top contact layer positioned on the liner layer and the bottom contact layer;
wherein the two bit line structures comprise an air gap disposed therebetween.

2. The semiconductor device of claim 1, wherein the bottom contact layer comprises tungsten, titanium, or titanium nitride.

3. The semiconductor device of claim 2, wherein the top contact layer comprises a material same as a material of the bottom contact layer.

4. The semiconductor device of claim 2, wherein a top surface of the top contact layer is lower than top surfaces of the plurality of bit line structures.

5. The semiconductor device of claim 4, wherein the liner layer comprises n-type dopants or p-type dopants.

6. The semiconductor device of claim 4, wherein the liner layer comprises doped polycrystalline silicon, doped polycrystalline germanium, or doped polycrystalline silicon germanium.

7. The semiconductor device of claim 4, wherein, from a top-view perspective, the bottom contact layer comprises a rectangular or square-shaped cross-sectional profile.

8. The semiconductor device of claim 1, further comprising a plurality of spacer structures positioned between the cell contact structure and the two bit line structures.

9. The semiconductor device of claim 8, wherein the plurality of spacer structures respectively comprises a bit line inner spacer positioned between one of the two bit line structures and the cell contact structure, a bit line middle spacer positioned between the bit line inner spacer and the cell contact structure, and a bit line outer spacer positioned between the bit line middle spacer and the cell contact structure.

10. The semiconductor device of claim 1, wherein the plurality of impurity regions are formed of silicon phosphide, phosphorus-doped silicon carbon, silicon carbide, silicon germanium, silicon-germanium-tin alloy, or silicon-germanium-boron alloy.
